(19) United States
(12) Patent Application Publication
(10) Pub. No.: US 2016/0267955 A1
(43) Pub. Date: Sep. 15, 2016

(54) MAGNETIC DOMAIN WALL MOTION MEMORY DEVICE

(71) Applicant: KABUSHIKI KAISHA TOSHIBA, Tokyo (JP)

(72) Inventor: Yoshihisa IWATA, Yokohama Kanagawa (JP)

(73) Assignee: KABUSHIKI KAISHA TOSHIBA, Tokyo (JP)

(21) Appl. No.: 14/818,512

(22) Filed: Aug. 5, 2015

Related U.S. Application Data
(60) Provisional application No. 62/130,473, filed on Mar. 9, 2015.

(51) Int. Cl. G11C 11/04

(52) U.S. Cl. CPC G11C 11/04

(57) ABSTRACT

A memory device according to one embodiment includes a magnetic wire; a conductive first line which faces one of opposite ends of the magnetic wire at a distance; and a conductive second line which faces the other of the opposite ends of the magnetic wire at a distance. A voltage applied to the first line is changed in a positive direction and a second voltage applied to the second line is changed in a negative direction to form a potential difference in the magnetic wire.

### CROSS-REFERENCE TO RELATED APPLICATIONS

This application claims the benefit of U.S. Provisional Application No. 62/130,473, filed Mar. 9, 2015, the entire contents of which are incorporated herein by reference.

### FIELD

Embodiments relate to a memory device.

### BACKGROUND

Magnetic domain wall motion memory devices using magnetic wires with magnetic domains are known.

### BRIEF DESCRIPTION OF THE DRAWINGS

FIG. 1 illustrates a related art;

FIG. 2 illustrates changes of currents in the related art of FIG. 1 with time;

FIG. 3 illustrates an example of functional blocks of a memory device of a first embodiment;

FIG. 4 is a circuit diagram of components involved in read and write of the memory device of the first embodiment;

FIG. 5 illustrates components and connections involved in magnetic wall shifts of the memory device of the first embodiment;

FIG. 6 illustrates a cross-section of a block of the memory device of the first embodiment;

FIG. 7 is a circuit diagram of one magnetic wire and components regarding magnetic wall shifts of the memory device of the first embodiment;

FIG. 8 illustrates output voltages of drivers of the memory device of the first embodiment with time;

FIG. 9 illustrates waveforms of the output voltages of the drivers of the memory device of the first embodiment and a result of simulation of waveforms of currents flowing through a magnetic wire with time;

FIG. 10 illustrates components and connections involved in magnetic wall shifts of the memory device of a first modification of the first embodiment;

FIG. 11 illustrates a cross-section of a block of the memory device of the first modification of the first embodiment;

FIG. 12 illustrates a plan view of a first example of a structure of the first modification of the first embodiment;

FIG. 13 illustrates a plan view of a second example of a structure of the first modification of the first embodiment;

FIG. 14 illustrates the section along line XIV-XIV of FIG. 13;

FIG. 15 illustrates one state in a process of manufacturing of the structure of the first modification of the first embodiment;

FIG. 16 illustrates a plan view of components involved in magnetic wall shifts of the memory device of a second modification of the first embodiment;

FIG. 17 illustrates the section along line XVII-XVII of FIG. 16;

FIG. 18 illustrates output voltages of drivers of a memory device of a second embodiment with time;

FIG. 19 illustrates waveforms of the output voltages of the drivers of the memory device of the second embodiment and a result of simulation of waveforms of currents flowing through a magnetic wire with time;

FIG. 20 illustrates an example of components and connections of drivers of the memory device of the second embodiment;

FIG. 21 illustrates a plan view of components involved in magnetic wall shifts of a memory device of a second modification of the third embodiment;

FIG. 22 illustrates the section along line XXII-XXII of FIG. 21;

FIG. 23A illustrates a first example of voltage application for magnetic wall shifts in a memory device of a third embodiment;

FIG. 23B illustrates the first example of voltage application for the magnetic wall shifts in the memory device of the third embodiment;

FIG. 24A illustrates a second example of voltage application for a magnetic wall shifts in the memory device of the third embodiment; and

FIG. 24B illustrates the second example of voltage application for the magnetic wall shifts in the memory device of the third embodiment.

### DETAILED DESCRIPTION

A memory device according to one embodiment includes a magnetic wire; a conductive first line which faces one of opposite ends of the magnetic wire at a distance; and a conductive second line which faces the other of the opposite ends of the magnetic wire at a distance. A voltage applied to the first line is changed in a positive direction and a second voltage applied to the second line is changed in a negative direction to form a potential difference in the magnetic wire.

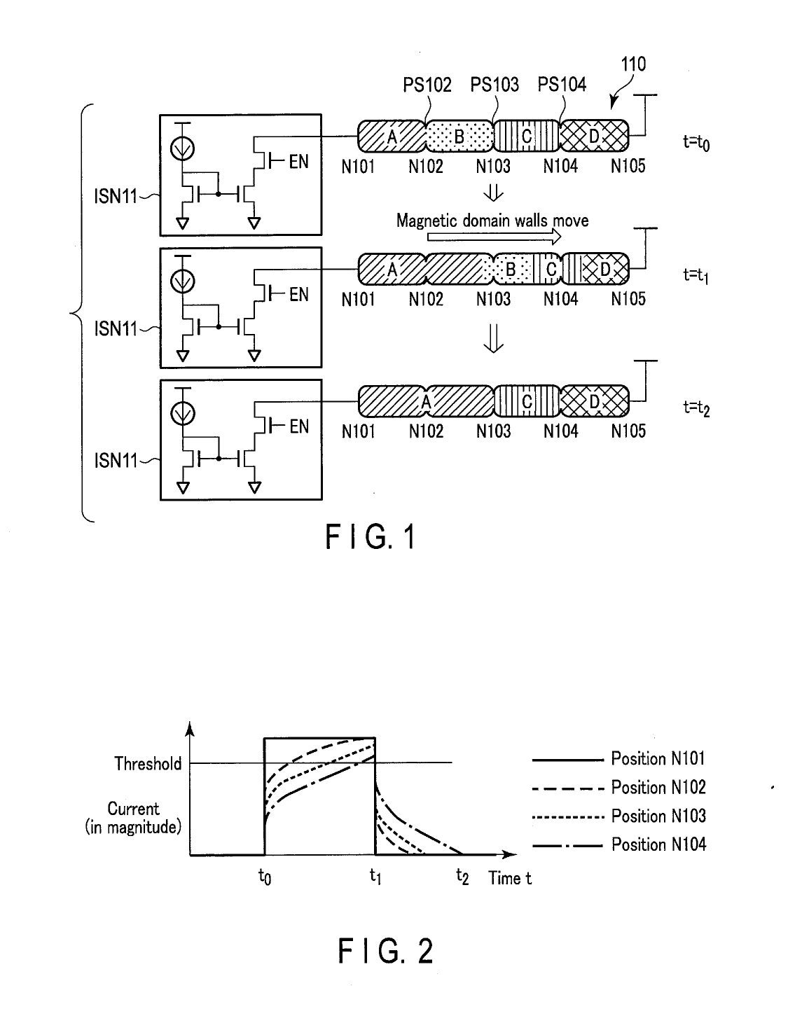

Magnetic wires of a magnetic domain wall motion memory have plural magnetic domains, and store independent data in each magnetic domain. A magnetic domain is the area surrounded by magnetic walls. For a read and write of data, a magnetic domain of a target for the read or write needs to be shifted to a position for a mechanism for read or write of data. To this end, the magnetic walls of the magnetic wire are shifted. The shift of magnetic walls can be implemented by sending current through the magnetic wire 110 as illustrated, for example, in FIG. 1. A component ISN11 is a current sink.

Each area among positions N101, N102, N103, N104, and N105 makes a magnetic domain. When a current is sent toward the position N101 from the position N105, or, an electron flow is sent toward the position N105 from the position N101, the magnetic walls move toward the direction contrary to the current. When a current of a magnitude over a threshold flows, the magnetic walls shift.

By sending current pulses to the magnetic wire one after another, the magnetic domain of the target for the data read or write is shifted to the position for the mechanism for read or write. The amount of shift of the magnetic walls by one current pulse corresponds to the size of an area storing one-bit data. For this reason, the length of the current pulse for shifting magnetic walls defines the size of data which can be stored in one magnetic wire. For example, assuming that the speed of a shift of magnetic walls is about 10 m/s, the amount of the shift of the magnetic walls by a current pulse of 10 ns is 100 nm. The shift amount of magnetic walls by a 20-ns current pulse is 200 nm, and that by a 50-ns current pulse is 500 nm. Therefore, in order to increase the storage capacity per unit length of a magnetic wire, a current pulse needs to be shorter.

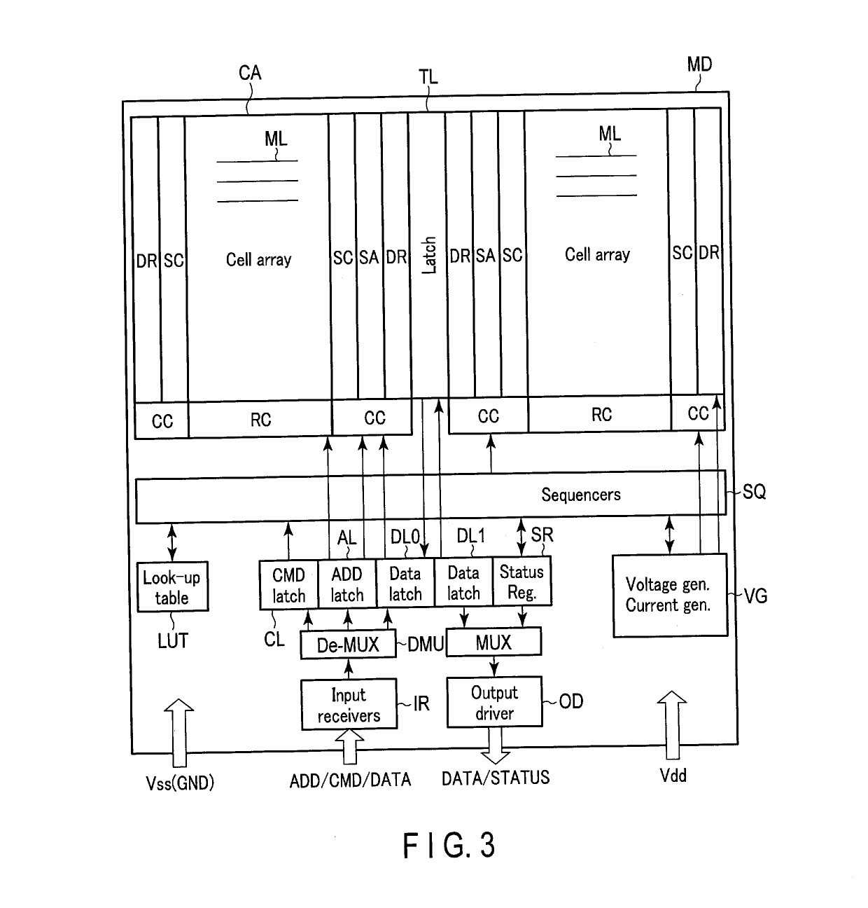

Moreover, waveforms of a current in different nodes collapse due to RC delays in the magnetic wire 110, and as a result, times for the current to reach the threshold to cause the shifts of magnetic walls after the start of flow of the current differ depending on the positions of nodes as illustrated in FIG. 2. Because of such collapses of the waveforms of the current, the magnetic walls at nodes in upper positions in the current flow shift before the shifts of the magnetic walls at nodes in lower positions in the current flow sufficiently progress. As a result, magnetic domains at lower positions in the current flow may disappear by the shifts of magnetic domains at upper positions in the current flow.

Embodiments will now be described with reference to figures. In the following description, components with substantially the same functionalities and configurations will be referred to with the same reference numeral, and repeated description may be omitted. Moreover, the description for a particular embodiment is also applicable as a description of another embodiment, unless stated otherwise. Furthermore, figures are schematic and the relationships between a thickness and a plane size of a layer and ratios of the thicknesses of layers may differ from actual ones. The figures may contain portions which may differ in relationships and ratios of dimensions over different figures.

### First Embodiment

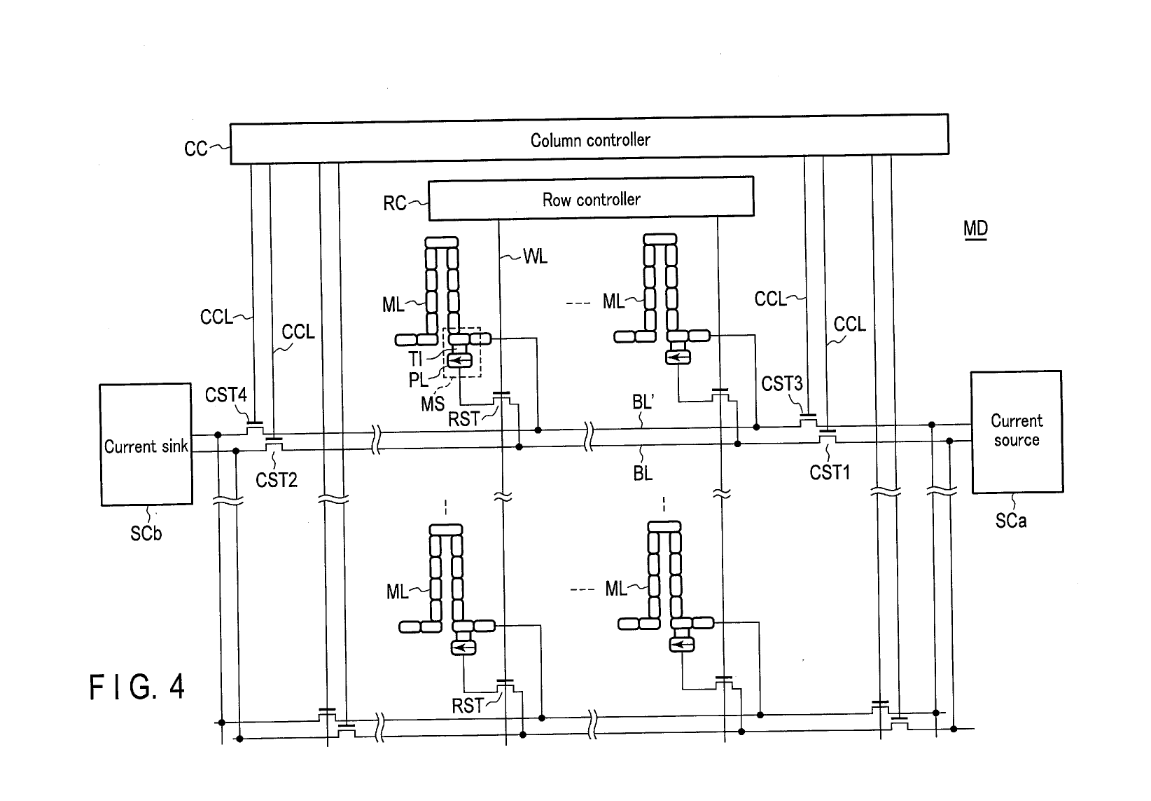

FIG. 3 illustrates an example of functional blocks of a magnetic domain wall motion memory device MD according to the first embodiment. The memory device MD includes a cell array CA. The cell array CA includes plural lines ML of a ferromagnetic material. The material of the magnetic wires (magnetic nanoribbons) ML can be, for example, a ferromagnetic material, such as Fe, Co, Ni, or combinations thereof, or may be a ferrimagnetic material in place of a ferromagnetic material as long as it has a conductivity. Each magnetic wire ML has plural magnetic domains along the direction in which it extends, and the magnetic moment in each magnetic domain is aligned. In other words, the magnetic domains are magnetized in fixed directions. Each magnetic domain can store one-bit data associated with the magnetization thereof. The magnetic wires ML are configured so that the magnetization orientation of each magnetic domain thereof can be changed. Each magnetic domain is magnetized parallel or anti-parallel with the direction in which the magnetic wires ML extend, for example.

The memory device MD is configured to write and read data in and from one or more selected magnetic domains. To this end, it includes a mechanism to write data in a particular magnetic domain, and a mechanism to read data from a particular magnetic domain, for example. A mechanism for read and/or write is implemented by a magnetic tunnel junction (MTJ) structure (not shown) which includes part of a magnetic wire as its storage layer, for example. An MTJ structure includes a storage layer with variable magnetization orientation, a pinned layer with a fixed magnetization orientation, and a tunnel insulator between the storage and pinned layers, as known by a person skilled in the art. The MTJ structure exhibits a high or low resistance in accordance with the magnetization orientations of the storage layer and pinned layer.

Current source and sink circuits SC supply a read current and write current, and draw the read current and write current. For example, the current source and sink circuits SC are provided at both sides of the cell array CA, and the current source and sink circuits SC at both sides of one cell array CA make a pair. Each pair of current source and sink circuits SC sends currents for read or write in conjunction. One of the current source and sink circuits SC operates as a current source, and the other operates as a current sink. The resultant flowing current is supplied to an MTJ structure including a magnetic domain of a read or write target. With this current, data is written in the write-target magnetic domain, and the resistance of the MTJ structure containing the read-target magnetic domain is distinguished.

Drivers DR receive voltages from the voltage and current generator VG, and output voltages of various values. The output voltages of the drivers DR are applied to components to generate a potential difference in a selected magnetic wire ML, and make this magnetic wire ML produce a voltage. With the voltage, the magnetic walls of the magnetic wire ML applied with the voltage and therefore the magnetic domains shift. The application of a voltage is repeated to shift magnetic domains plural times to shift the read or write target magnetic domain to the position of the MTJ structure for read or write.

The row controllers RC receive an address signal, and, based on the row address in the received address signal, electrically couple a specified magnetic wire ML to other related components. The column line controllers CC receive an address signal, and based on the column address in the received address signal, electrically couple a specified magnetic wire ML in a specified column to other related components. Sense amplifiers SA sense data from the cell arrays CA. Latch TL temporarily stores data from the magnetic wires ML, or data to the magnetic wires ML.

A sequencer SQ manages the operation of the whole memory device MD based on a reference table LUT, a command latch CL, and an address latch AL. The reference table LUT stores information, including various kinds of parameters. The command latch CL, the address latch AL, and the data latch DL0 receive commands CMD, an address signal ADD, and data DATA from outside the memory device MD through the input receiver IR and the demultiplexer DMU, respectively. The data latch DL0 supplies the received data to the column controllers CC and the latch TL. The input receiver IR controls the input of signals. The data latch DL1 receives data from the latch TL. The data latch TL and the status register SR output data DATA and status information STATUS to outside the memory device MD through a multiplexer MUX and the output driver OD, respectively.

The memory device MD receives a power supply potential Vdd and a common (or, ground) potential Vss (GND) from outside. The voltage and current generator VG generates various voltages and currents for the operation of memory device MD based on the power supply received from outside and the control of sequencer SQ.

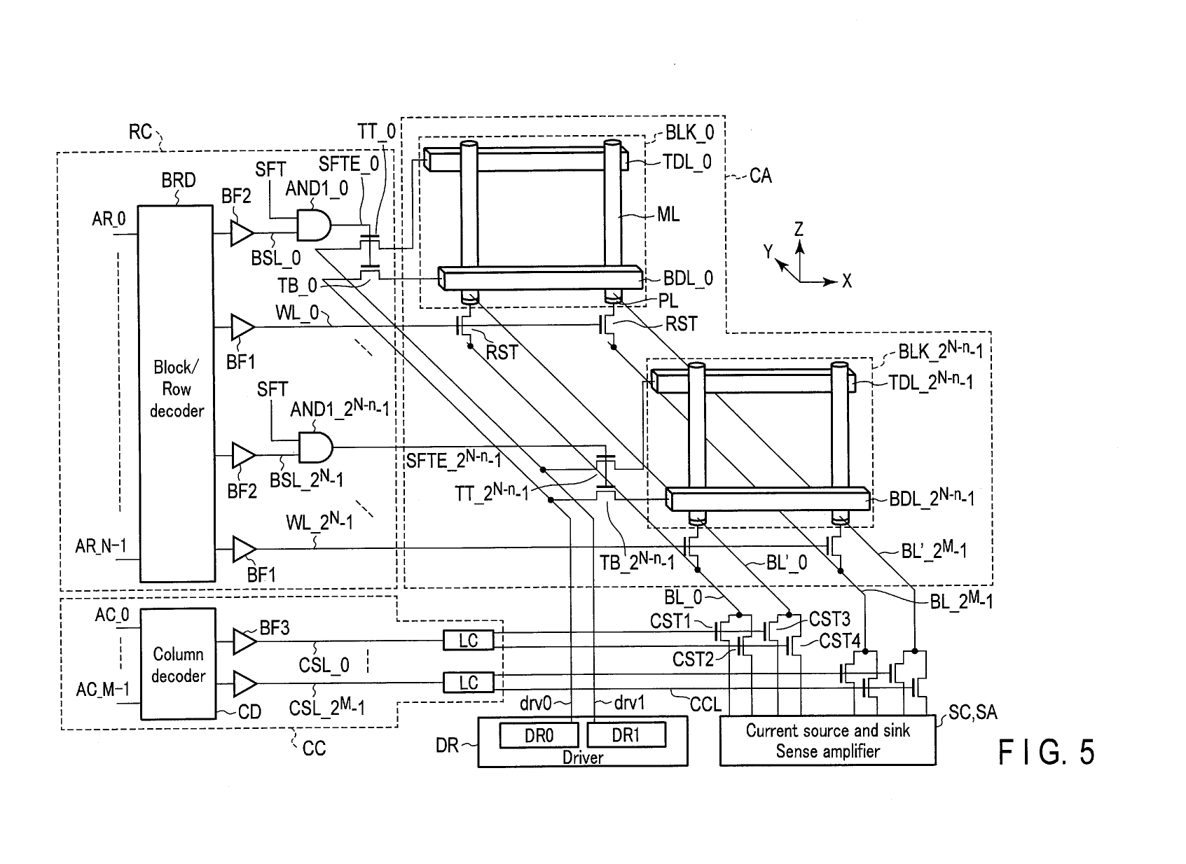

Referring to FIG. 4, the read and write of the memory device of the first embodiment will be described. FIG. 4 is a circuit diagram of components involved in the read and write of the memory device. Plural magnetic wires ML are illustrated in FIG. 4. The shape of magnetic wires ML is not limited to the FIG. 4 example, and may be, for example, a straight line. The magnetic wires ML have plural pinning sites. A pinning site is a position in which magnetic walls of a magnetic wire ML is easily stabilized. A pinning site can be implemented by making it narrower in the magnetic wire ML than those in other positions, or, forming a constriction. The pinning sites are located at equal intervals along a magnetic wire ML.

Each magnetic wire ML is provided with a structure described in the following. A pinned layer PL is provided along a particular position in each magnetic thin line ML. The pinned layer PL has its orientation of magnetization fixed, and the orientation of magnetization accords to a direction in which the magnetic wire ML extends. A tunnel insulator TI is provided between the magnetic wire ML and pinned layer PL. The pinned layer PL is provided in a position, the shape, and a direction which make an MTJ structure MS with one magnetic domain in the magnetic wire ML and tunnel insulator TI, for example. Specifically, for example, the pinned layer PL has a similar or substantially the same length as one magnetic domain in the magnetic wire ML and/or that of the area between two adjacent pinning sites in the magnetic wire ML. The position of MTJ structure MS is not limited to the FIG. 4 example, but can be anywhere in the magnetic wire ML.

In a read of data from a particular magnetic domain of a particular magnetic wire ML, the read target magnetic domain is shifted to the position facing the pinned layer PL. At the position after shift, a current is sent in the direction which extends through each layer in the MTJ structure MS, and, based on the value of the current, the data in the target magnetic domain is distinguished. Specifically, based on the current, it is determined whether the orientation of magnetization of the read target magnetic domain is parallel or anti-parallel to that of the pinned layer PL. A current through an MTJ structure MS in the parallel case is larger than that in the anti-parallel case.

In a write of data into a particular magnetic domain of a particular magnetic wire ML, the write target magnetic domain is shifted to the position facing the pinned layer PL. At the position after shift, a current is sent in the direction which extends through each layer of the MTJ structure MS, and, with the current, data is written in the write target magnetic domain. The value of the data to be written depends on the direction of current. With a current from the pinned layer PL to the write target magnetic domain, one value of one-bit data (for example, “1”) is written. In contrast, with a current from the write target magnetic domain to the pinned layer, the other value of one-bit data (for example, “0”) is written.

Components for supplying such currents for the read and write in the magnetic domains in one or more selected magnetic wires ML are further provided. The surface of pinned layer PL opposite to the tunnel insulator TI is coupled to one end of a row select transistor RST. The row select transistor RST is, for example, an n-type metal oxide semiconductor (MOS) transistor.

Sets of such a magnetic wire ML, pinned layer PL, insulator TI, and transistor RST are arranged in a matrix.

The gate of each transistor RST is coupled to the row controller RC. Plural transistors RST from a row are coupled to a word line WL at its gate. The word lines WL transmit row control signals. The row control signals are generated by the row controller RC. A transistor RST is turned on when it receives an asserted row control signal.

The row controller RC asserts, among the row control signals for different rows, one specified by a row address.

The other end of each of transistors RST from the same column is coupled to a bit line BL. Each bit line BL is coupled to a current source SCa of a pair of current source and sink circuits SC through a column select transistor CST1, and coupled to a current sink SCb through a column select transistor CST2. The transistors CST1 and CST2 are n-type MOS transistors, for example.

One end of each magnetic wire ML from the same column is coupled to a bit line BL′. Each bit line BL′ is coupled to a current source SCa through a column select transistor CST3, and coupled to a current sink SCb through a column select transistor CST4. The transistors CST3 and CST4 are n-type MOS transistors, for example. The bit lines BL are further coupled to the sense amplifiers SA of FIG. 3. The sense amplifiers SA are omitted in FIG. 4.

A set of transistors CST1 to CST4 is provided for each column. Each gate of the transistors CST1 to CST4 is coupled to a corresponding control signal line CCL. The control signal lines CCL transmit column control signals. The column control signals are generated by the column controller CC. The control signal lines CCL are independent for each column. Furthermore, the control signal lines CCL for the transistors CST1 to CST4 are also independent from each other. The transistors CST1 to CST4 are turned on when the column control signals which they are receiving on the control signal lines CCL are asserted. In only one column in a selected row, one or more of the transistors CST1 to CST4 receive asserted column control signals. One column is selected by supply of asserted column control signals to couple one MTJ structure MS of the selected column between one pair of current source and sink SCa and SCb. The current source and sink SCa and SCb, the combination of the turned-on transistors among transistors CST1 to CST4 in the selected column is varied by the column controller CC to supply a read current or a write current in a certain direction based on the data to be written in a selected MTJ structure MS. A detailed example is given below.

For a read, the transistors CST1 and CST4 are turned on in the selected column to make the current source SCa supply a read current and make the current sink SCb draw the current. With this, the read current flows through the selected MTJ structure MS from the pinned layer PL toward the magnetic wire ML.

For a “1” data write, the transistors CST1 and CST4 are turned on in the selected column to make the current source SCa supply a write current and make the current sink SCb draw the current. With this, the write current flows through the selected MTJ structure MS from the pinned layer PL toward the magnetic wire ML to write “1” data in the selected magnetic domain.

For a “0” data write, the transistors CST2 and CST3 are turned on in the selected column to make the current source SCa supply a write current and make the current sink SCb draw the current. With this, the write current flows through the selected MTJ structure MS from the magnetic wire ML toward the pinned layer PL to write “0” data in the selected magnetic domain.

The mechanism for the read and write of data is not limited to the above example. For example, a set of the pinned layer and a tunnel insulator may be provided for each of the data read, “0” data write and “1” data write.

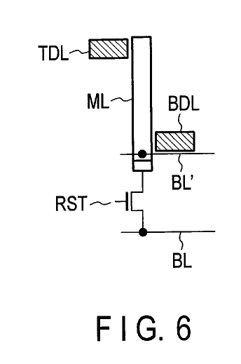

The memory device MD further includes a mechanism for shifting magnetic walls (or, magnetic domains). As such a mechanism, each magnetic wire ML is provided with the structure described below. The mechanism for magnetic wall shift will be described with reference to FIG. 5. FIG. 5 illustrates components and connections involved in the magnetic wall shift of the memory device of the first embodiment. FIG. 5 includes in part a perspective view of the structure of components, and illustrates connections of components in the remaining part.

As illustrated in FIG. 5, the cell array CA includes plural magnetic wires ML which extend along an axis (z-axis) perpendicular to the surface of a substrate (not shown). Some magnetic wires ML make a block BLK (or, are included in a block). Each magnetic wire ML is accompanied by an MTJ structure MS for read and write. The MTJ structure MS is located at, along the z-axis, the bottom of each magnetic wire ML, for example. Specifically, the bottom of each magnetic wire ML faces the tunnel insulator TI (not shown), which faces the pinned layer PL (not shown).

The magnetic thin wires ML are arranged in 2^{N} rows and 2^{M} columns in the plane made of x and y directions. The magnetic thin wires ML extend along the z-axis, and are located above, along the z-axis, the substrate. Magnetic thin wires ML from the same row make a set. Each block BLK includes plural, for example 2ⁿ (0≦n≦N) sets of magnetic thin wires ML. Therefore, a cell array CA includes 2^{N-n} blocks of BLK_0 to BLK_2^{N-n}−1.

Each MTJ structure MS is coupled to one end of a row select transistor RST at a side opposite to a magnetic wire ML, or, at its pinned layer PL (not shown). The MTJ structure MS and row select transistor are coupled in series.

The other end of each of plural (or, all) row select transistors RST from the 0^{th} column is coupled to a bit line BL_0. Similarly, the other end of each in a set of (or, all) the row select transistors RST from the Q^{th} (0≦Q≦2^{M}−1) column is coupled to a bit line BL_Q at the side opposite to the MTJ structure MS.

Plural (or, all) magnetic thin wires ML from the 0^{th} column are coupled to a bit line BL′_0. Similarly, a set of (or, all) the magnetic thin wires ML from the Q^{th} row is coupled to a bit line BL′_Q. The magnetic wires are coupled to the bit lines BL′ at, for example the bottom along the z-axis. The bit lines BL_0 and BL′_0 make a pair. Similarly, the bit line BL_Q and BL′_Q make a pair.

Plural (or, all) row select transistors RST from the 0^{th} row are coupled to a word line WL_0 at the gates. Similarly, plural (or, all) row select transistors RST from the R^{th} (0≦R≦2^{N}−1) row are coupled to a word line WL_R at the gates.

The row controller RC includes a block-decoder/row-decoder BRD. The block-decoder/row-decoder receives row address signals AR_0 to AR_N−1. Each of the row address signals AR_0 to AR_N−1 includes 0^{th} to n−1^{th} bits, and the set of 0^{th} to n−1^{th} bits specifies one block BLK and one word line WL. The block-decoder/row-decoder selects one block BLK and one word line WL in one cell array CA based on the received row address signals AR_0 to AR_N−1. Specifically, for example, the row controller RC includes buffers BF1 coupled to respective word lines WL_0 to WL_2^{N}−1. The block-decoder/row-decoder BRD supplies an asserted signal to one word line WL selected based on the row address signals AR_0 to AR_N−1 via the corresponding buffer BF1.

The block-decoder/row-decoder BRD also outputs block select signals BSL_0 to BSL_2^{N-n}−1. In order to select a block BLK specified by the row address signals, the block-decoder/row-decoder BRD supplies a selected one of the block BLK_0 to BLK_2^{N-n}−1 with a corresponding one of block select signals BSL_0 to BSL_2^{N-n}−1 via the corresponding buffer BF2. The block select signals BSL_0 to BSL_2^{N-n}−1 are supplied to AND gates AND1_0 to AND1_2^{N-n}−1, respectively. The AND gates AND1_0 to AND1_2^{N-n}−1 further receive a signal SFT, and output signals SFTE_0 to SFTE_2^{N-n}−1, respectively. The signal SFTE_0 is supplied to respective gates of gate transistors TT_0 and TB_0. Similarly, the signal SFTE_S is supplied to respective gates of gate transistors TT_S and TB_S. The gate transistors TT_0 to TT_2^{N-n}−1, and TB_0 to TB_2^{N-n}−1 are each made of an n-type MOSFET, for example.

The connections of the bit lines BL are as described with reference to FIG. 4. Here, the parts which are not shown in FIG. 4 will be described.

The column controller CC includes a column decoder CD. The column decoder CD receives column address signals AC_0 to AC_M−1. The column address signals AC_0 to AC_M−1 respectively include 0^{th} to M−1^{th} bits, and the set of 0^{th} to M−1^{th} bits specifies one column. The block-decoder/row-decoder BRD selects one column in one cell array CA based on the received column address signals AC_0 to AC_M−1. Specifically, for example, the column controller CC includes buffers BF3 respectively coupled to column control lines CSL_0 to CSL_2M−1. The column decoder CD supplies a column control line CSL selected based on the column address signals AC_0 to AC_M−1 with the asserted column select signal through the corresponding buffer BF3.

The column controller CC further includes logic circuits LC, each of which receives a column select signal (i.e., a signal on a column control line CSL) and further receives operation control signals from the sequencer SQ (not shown). The logic circuit LC for a selected column receives an asserted column select signal. The logic circuit receiving an asserted column signal outputs asserted column control signals on two column control signal lines CCL specified based on operations instructed by the operation control signals (i.e., the read, “0” data write, or “1” data write) to turn on two of the column control transistors CST1 to CST4 in the selected column. As a result, in the selected column, the bit lines BL and BL′ are coupled to the current source and sink circuits SC or the sense amplifier SA as described above.

Each magnetic wire ML is coupled with a capacity at each of both ends. The capacity can be implemented by, for example, the magnetic wire ML and conductive interconnects TDL and BDL which face the magnetic wire ML with an interval. The cell array CA further includes such interconnects TDL and BDL.

A block BLK_0 is provided with two interconnects TDL_0 and BDL_0. Similarly, a block BLK_S (0≦S≦2^{N-n}−1) is provided with interconnects TDL_S and BDL_S. The interconnects TDL (TDL_0 to TDL_2^{N-n}−1) and the interconnects BDL (BDL_0 to BDL 2^{N-n}−1) extend along the x-axis.

In each block BLK, the interconnects TDL are provided near the upper, along the z-axis, ends of plural (or, all) magnetic wires ML of that block BLK. In each block BLK, the interconnects BDL are provided near the lower, along the z-axis, ends of plural (or, all) magnetic wires ML of that block BLK. Each interconnect TDL or BDL faces the surface of corresponding magnetic wire ML which extends in the direction in which the magnetic wire ML extends (the direction along the z-axis), i.e., side surface. In each block BLK, the interconnect TDL and the interconnect BDL sandwich plural (or, all) magnetic wires ML in that block BLK. The interconnect TDL and the part of each magnetic wire ML facing the interconnect TDL serve as electrodes to make a capacitor element. Similarly, the interconnect BDL and the part of each magnetic wire ML facing the interconnect BDL serve as electrodes to make a capacitor element.

The interconnect TDL_0 of the block BLK_0 is coupled to the output node of a driver DR1 via a transistor TT_0. The driver DR1 is included in the driver DR and outputs a voltage drv1 at the output node. Similarly, the interconnect TDL_S of the block BLK_S is coupled to the output node of the driver DR1 via a transistor TT_S.

The interconnect BDL_0 of the block BLK_0 is coupled to the output node of a driver DR0 via a transistor TB_0. The driver DR0 is included in the driver DR and outputs a voltage drv0 at the output node. Similarly, the interconnect BDL_S of the block BLK_S is coupled to the output node of the driver DR0 via a transistor TB_S.

The drivers DR0 and DR1 receive voltages from the voltage and current generator VG. The drivers DR0 and DR1 use the received voltage, and in conjunction apply voltages of particular waveforms to the interconnects TDL and BDL to generate a variable potential difference in the corresponding magnetic wire ML between the part facing the interconnect TDL and the part facing the interconnect BDL.

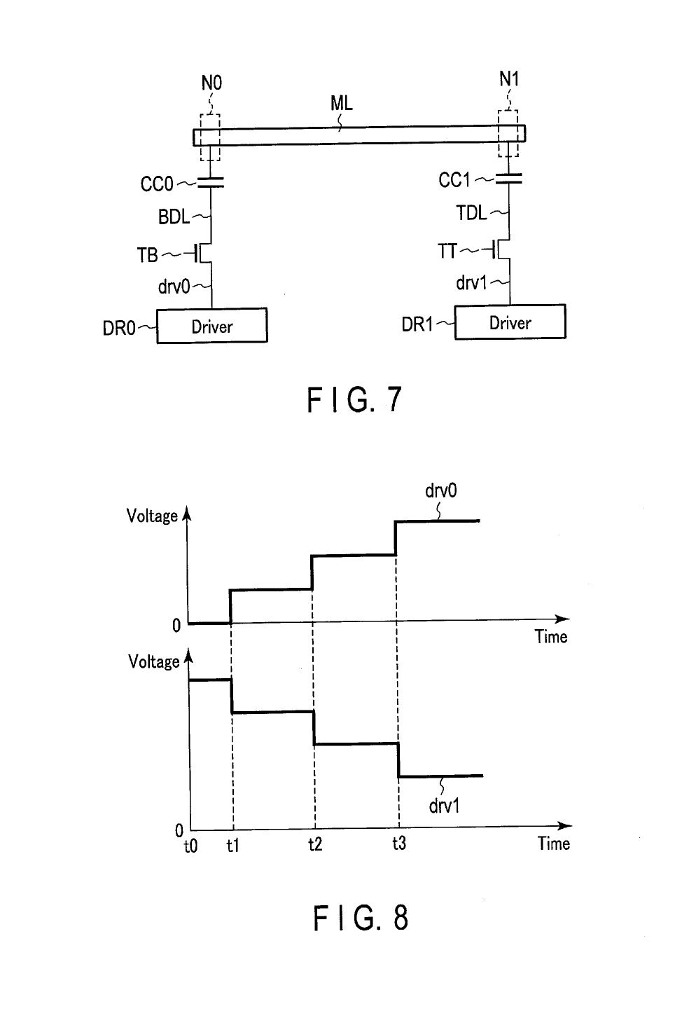

A section of the block BLK along the y-axis is illustrated in FIG. 6. Only one interconnect TDL and one interconnect BDL are provided in each block BLK as illustrated in FIGS. 5 and 6. Positions at coordinates on the z-axis between the interconnects TDL and BDL are free from an interconnect which is (directly) coupled to the drivers DR0 and DR1 and in which current flows. However, some sort of interconnect may be provided.

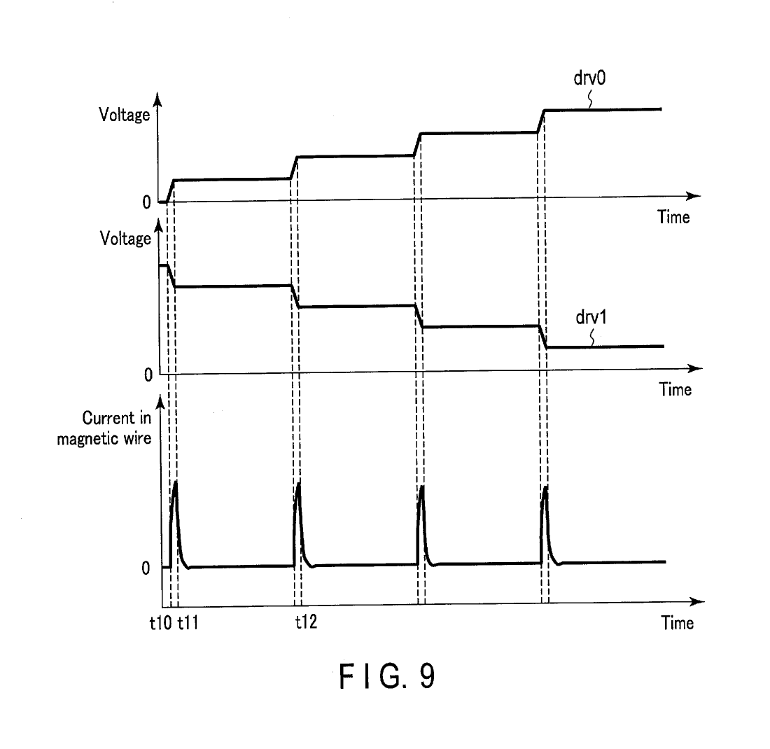

Magnetic wall shift in the memory device of the first embodiment will now be described with reference to FIGS. 7 to 9. FIG. 7 is a circuit diagram of one magnetic wire and components involved in magnetic wall shift of the memory device of the first embodiment. As described above, each magnetic wire ML has a capacity coupled at each of both ends. This is represented in FIG. 7. As illustrated in FIG. 7, the magnetic wire ML has a capacity CC0 coupled at a position N0 and a capacity CC1 at a position N1. The positions N0 and N1 are, for example, the ends of the magnetic wire ML. The capacity CC0 is implemented by the interconnect BDL facing the magnetic wire ML and the part of the magnetic wire ML. The capacity CC1 is implemented by interconnect TDL facing the magnetic wire ML and the part of the magnetic wire ML.

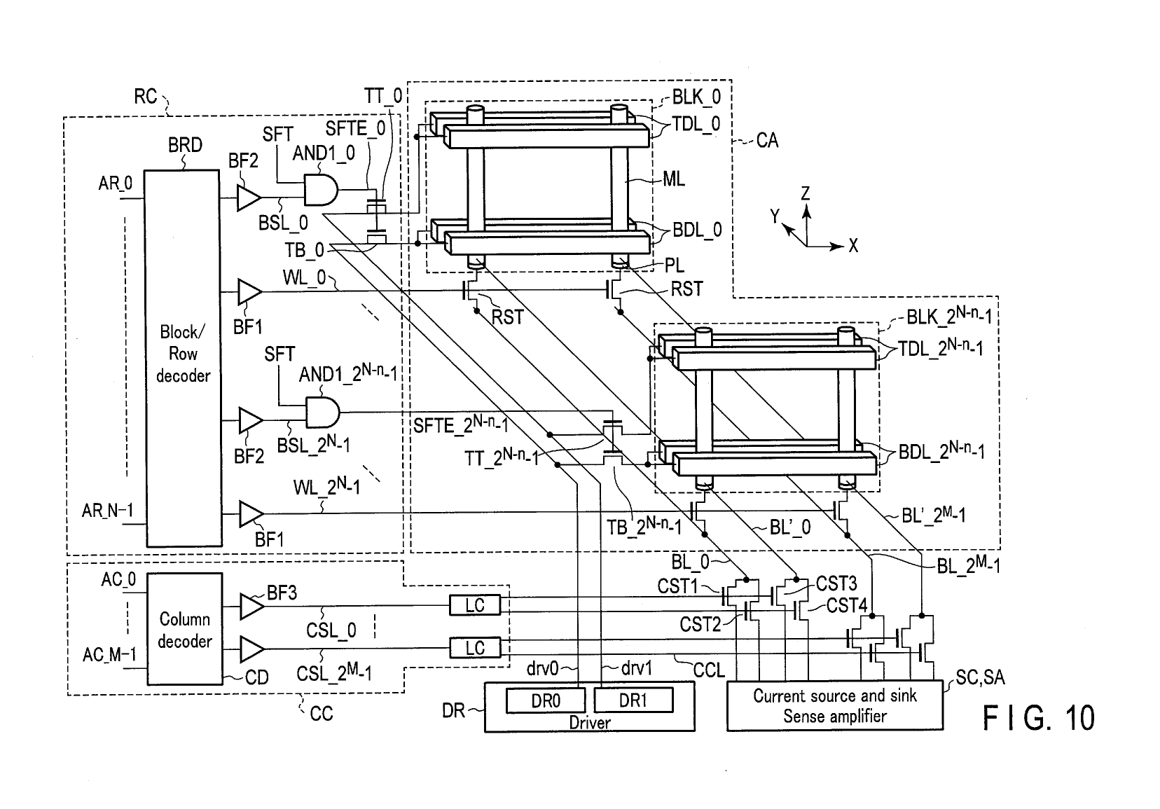

FIG. 8 illustrates the output voltages drv0 and drv1 of the driver DR of the memory device MD of the first embodiment with time. The transistors TT and TB coupled to the interconnects TDL and BDL for the magnetic wire ML whose magnetic walls will be shifted remain on during the operation illustrated in FIG. 8 and are described in the following. As a result, during the operation, the interconnect TDL and therefore the electrode of the capacity CC0 opposite to the magnetic wire ML is electrically coupled to the output node drv1 of the driver DR1, and the interconnect BDL and therefore the electrode of the capacity CC1 opposite to the magnetic wire ML is electrically coupled to the output node drv0 of the driver DR1. FIG. 8 illustrates the waveforms of the output voltage drv0 of the driver DR0 and the output voltage drv1 of the driver DR1. The drivers DR0 and DR1 output the voltages drv0 and drv1, illustrated in FIG. 8 and described in the following, and apply them to the interconnects BDL and TDL.

The shift of magnetic walls starts at time t0, i.e., when the transistors TT and TB turn on at time t0, and remain on after that. The driver DR0 raises the voltage drv0 stepwise with time from time t0 based on the instruction of the sequencer SQ. The driver DR1 lowers the voltage drv1 stepwise with time from time t0 based on the instruction of the sequencer SQ. For example, the voltages drv0 and drv1 have zero and positive values at time t0, respectively.

The rise of the voltage drv0 and the fall of the voltage drv1 are started at a similar timing, or at substantially the same timing, for example. In FIG. 8, both the rise of the voltage drv0 and the fall of the voltage drv1 are started at time t1, t2, and t3. The quantity of a rise of the voltage drv0 and that of a fall of the voltage drv1 at a particular timing have similar values, or the same value, for example.

With the above features, the waveform of the voltage drv0 and the waveform of the output voltage drv1 are line-symmetrical with respect to the horizontal axis, for example.

With the rise of the output voltage drv0, the potential at the position N0 of the magnetic wire ML rises through the capacity coupling. This rise follows the rise of the voltage drv0. With the fall of the output voltage drv1, the potential at the position N1 of the magnetic wire ML falls through the capacity coupling. This fall follows the fall of the voltage drv1. The rise of the potential at the position N0 in the magnetic wire ML and the fall of the potential at the position N1 in the magnetic wire ML generate a potential difference between the positions N0 and N1. With this potential difference, a current flows from the position N0 toward the position N1 in the magnetic wire ML. With this current, the magnetic walls and therefore the magnetic domains in the magnetic wire ML are shifted from the side of the position N1 to the side of position N0.

In order to form such a potential difference between the positions N1 and N2 in the magnetic wire ML, the rise of the voltage drv0 has the inclination of a magnitude which allows the potential at the position N0 to change (i.e., rise) by the capacity coupling. Similarly, the fall of the voltage drv1 has the inclination of a magnitude which allows the potential at the position N1 to change (i.e., fall) by the capacity coupling.

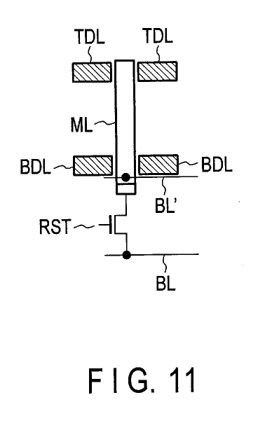

FIG. 9 illustrates the waveforms of the voltages drv0 and drv1 with time and a result of a simulation of the waveforms of a current which flows through the magnetic wire ML with time. As illustrated in FIG. 9, the waveforms of the voltages drv0 and drv1 are as described above with reference to FIG. 8. The rise of the voltage drv0 and the fall of the voltage drv1, however, have inclinations due to the RC delay of the drivers DR0 and DR1, the transistors TB and TT, the interconnects BDL and TDL, and interconnects that connect them.

The rise of the voltage drv0 and the fall of the voltage drv1 make a current flow in the magnetic wire ML during the rise of the voltage drv0 and the fall of the voltage drv1. The waveform of this current rises over the period of the rise of the voltage drv0 and the fall of the voltage drv1, or, the period over which the voltages drv0 and drv1 change (or, are driven), such as a period from t10 to t11, for example. The waveform of the current then returns to zero due to constancy of the voltages drv0 and drv1. This is because the potential difference in the magnetic wire ML caused by the capacity coupling disappeared.

Thus, the waveform of the current rises over the period of the rise of the voltage drv0 and the fall of the voltage drv1, and therefore the shorter the period required for the rise of the voltage drv0 and the fall of the voltage drv1, the shorter the period over which the current pulse is generated, and, strictly speaking, the shorter the period over which the current pulse rises. For example, when the rise of the voltage drv0 and the fall of the voltage drv1 are performed in ins, a current pulse with as short a width as Ins can be generated as in the FIG. 9 example. The width of such a current pulse is short, and the width of the current pulse generated by application of the current to the magnetic wire ML is also short. A small current pulse width as obtained with the first embodiment cannot be obtained through application of a current to the magnetic wire ML.

The magnitude of the current pulse depends on the magnitude of change of the rise of the output voltage drv0 per unit time and the magnitude of change of the fall of the output voltage drv1 per unit time. The larger the magnitudes of the change of the rise and fall per unit, the larger the magnitude of the current pulse. The magnitude of the increase of change of the voltage drv0 per unit time and the magnitude of the decrease of change of the voltage drv1 per unit time are set to allow the current pulse to have a magnitude equal to or larger than a minimum (threshold) current required for the magnetic walls in the magnetic wire ML to shift.

With the timing and magnitude of the rise of the voltage drv0 aligned with the timing and magnitude of the fall of the voltage drv1, the waveforms of the current pulse at plural positions in the magnetic wire ML become more uniform.

The voltages drv0 and drv1 remain the same magnitudes over a period after the rise or fall. During this period over which the waveforms of the voltage drv0 and drv1 are flat (for example, a period from time t11 to t12), a read or write is executed to the magnetic domain of the MTJ structure MS.

As described above, the interconnects TDL and BDL make a capacity with the plural magnetic wires ML (in one block BLK). For this reason, application of the output voltages drv0 and drv1 make the magnetic walls shift in the plural magnetic wires ML which share the interconnects TDL and BDL.

As described, according to the first embodiment, the magnetic wires ML have the capacities CC0 and CC1 coupled at both ends, and potential differences are generated in the magnetic wires ML by the rise of the potential through one of the capacities CC0 and CC1 and the fall of the potential through the other. With such potential differences, current flows in the magnetic wires ML, the pulse width of this current is significantly short, and is shorter than the width of a current pulse that would be generated by application of a current to the magnetic wires ML. The length of the possible magnetic domains in the magnetic wires ML depends on the length of a current pulse, and therefore the realization of a short current pulse can decrease the length of the magnetic domains. This increases the storage capacity per unit length of the magnetic wires, and can realize the memory device MD with an increased capacity.

(First Modification of First Embodiment)

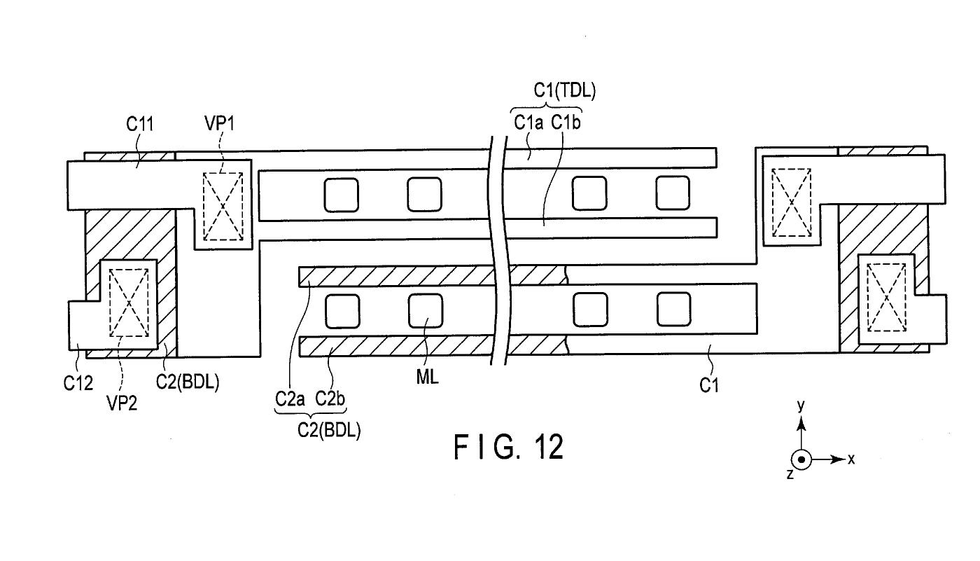

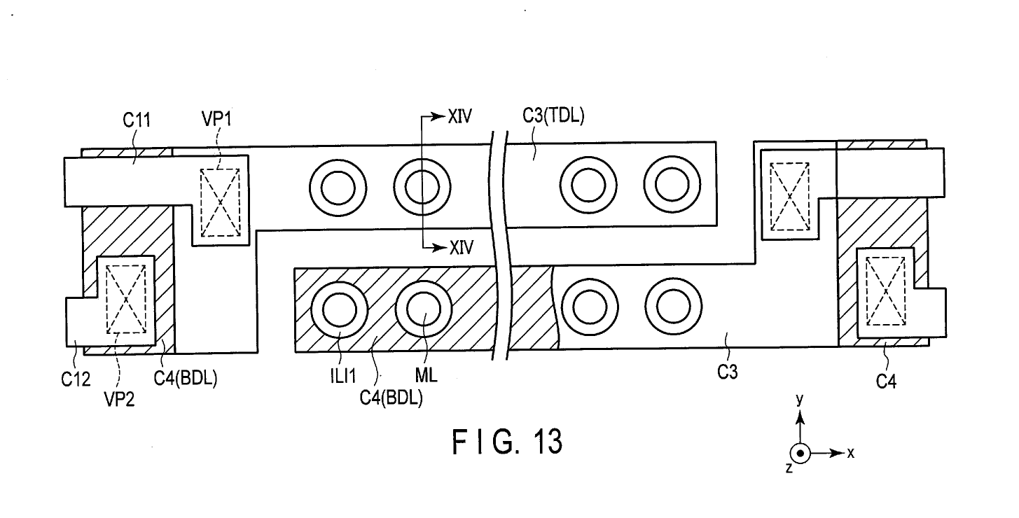

FIG. 10 illustrates part of a cell array of a memory device MD of a first modification of the first embodiment, and components and connections involved in a magnetic wall shift. FIG. 10 includes in part a perspective view of the structures of components, and illustrates connections of components in the remaining part as in FIG. 5. FIG. 11 illustrates a section of a block of the memory device MD of the first modification of the first embodiment.

In each block, in addition to the interconnect TDL of FIG. 5, an additional interconnect TDL is provided as illustrated in FIGS. 10 and 11. The two interconnects TDL sandwich the set of the magnetic wires ML in this block BLK, are electrically coupled to each other, and are both driven by a driver DR0.

Similarly, in each block, in addition to the interconnect BDL of FIG. 5, an additional interconnect BDL is provided. The two interconnects BDL sandwich the set of the magnetic wires ML in this block BLK, are electrically coupled to each other, and are both driven by a driver DR1.

Each block BLK is only provided with a pair of interconnects TDL and a pair of interconnects BDL. Positions at coordinates on the z-axis between the interconnects TDL and the interconnects BDL are free from interconnects coupled to the drivers DR0 and DR1. However, some sort of interconnect may be provided.

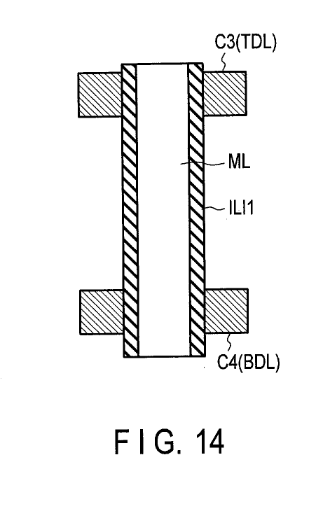

FIG. 12 illustrates a first example of the structure for implementing the structure of FIG. 10, and illustrates a view of this structure when seen from above. FIG. 12 illustrates two blocks BLK. In each block BLK, the magnetic wires ML line up along the x-axis. Conductive layers C1 are provided along the x-axis. A conductive layer C1 extends along the x-axis, has a thickness along the z-axis, and includes a first section C1a and a second section C1b. The first section C1a and the second section C1b sandwich a set of the magnetic wires ML. The first section C1a serves as one of the two interconnects TDL, and the second section C1b serves as the other of the two interconnects TDL.

The first section C1a and the second section C1b are coupled to each other outside the set of the magnetic wires ML. The tops of the conductive layers C1 are coupled to conductive layers C11 through conductive via plugs VP1.

Furthermore, conductive layers C2 are provided below, along the z-axis, the conductive layers C1. A conductive layer C2 has a thickness along the z-axis, and has a shape similar to the conductive layer C1 along the xy-plane. Specifically, a conductive layer C2 has a first section C2a along the first section C1a of the conductive layer C1, and a second section C2b along the second section C1b of the conductive layer C1. The first section C2a of the conductive layer C2 serves as one of the two interconnects BDL, and the second section C2b serves as the other of the two interconnects BDL. The first section C2a and the second section C2b of a conductive layer C2 are coupled to each other outside a set of the magnetic wires ML, and are coupled to a conductive layer C12 through another conductive via plug VP2.

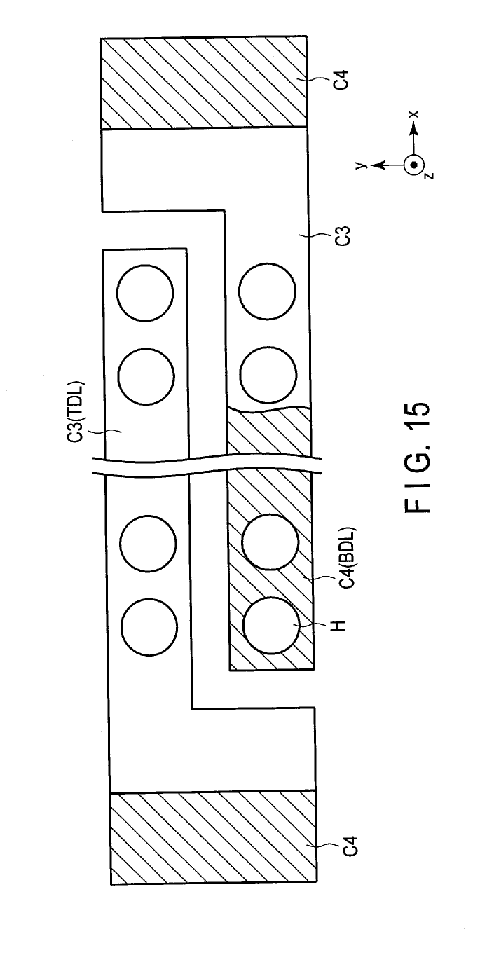

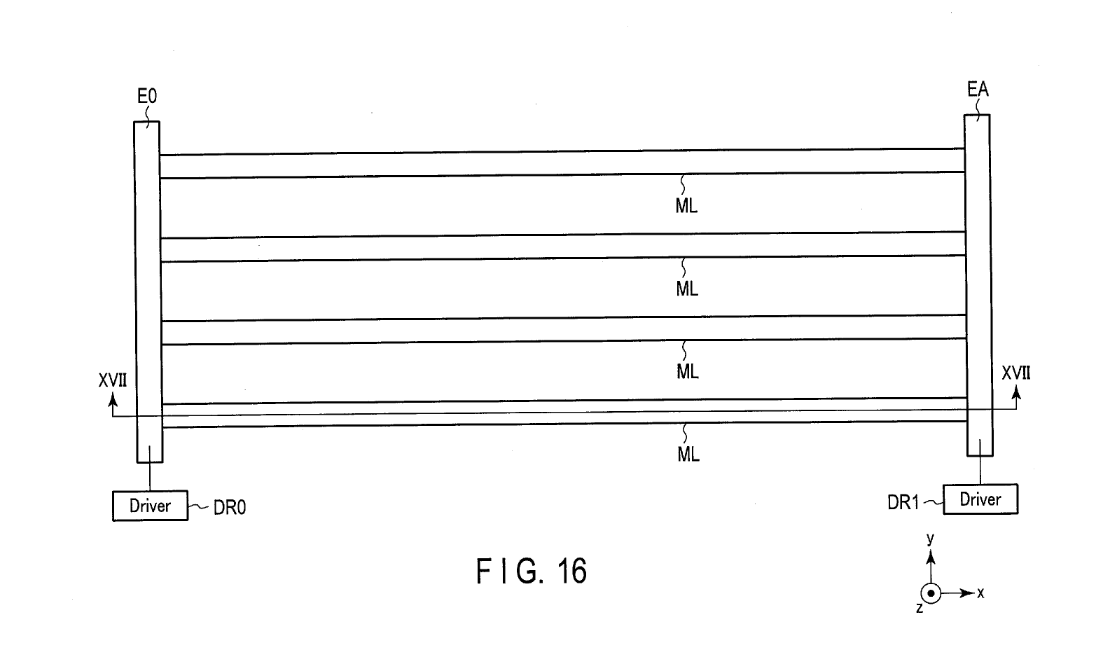

FIG. 13 illustrates a second example of the structure for implementing the structure of FIG. 10, and illustrates a view of this structure when seen from above. FIG. 14 illustrates the section along line XIV-XIV of FIG. 13.

FIG. 13 illustrates two blocks BLK. In each block BLK, the magnetic wires ML line up along the x-axis. The sides of each magnetic wire ML are covered with an insulator ILI1. Each insulator ILI1 has a cylindrical shape, and is in contact with the side of a magnetic wire ML within it.

Conductive layers C3 are provided along the x-axis. The conductive layers C3 extend along the x-axis, have a thickness along the z-axis, and have a larger length than the outer diameter of the insulators ILI1 along the y-axis, and cover the sides of plural (or, all) insulators ILI1 in one block. The conductive layers C3 serve as the interconnects TDL. The conductive layers C3 are coupled to conductive layers C11 through via plugs VP1.

Conductive layers C4 are provided below, along the z-axis, the conductive layers C3. The conductive layers C4 have a thickness, and have a shape similar to the conductive layers C3 along the xy-plane. Specifically, the conductive layers C4 have a larger length than the outer diameters of insulators ILI1 along the y-axis, and cover the sides of plural (or, all) insulators ILI1 in one block. The conductive layers C4 serve as the interconnects BDL. The conductive layers C4 are coupled to conductive layers C12 through via plugs VP2.

Such a structure can also implement a structure equivalent to the structure of FIG. 12.

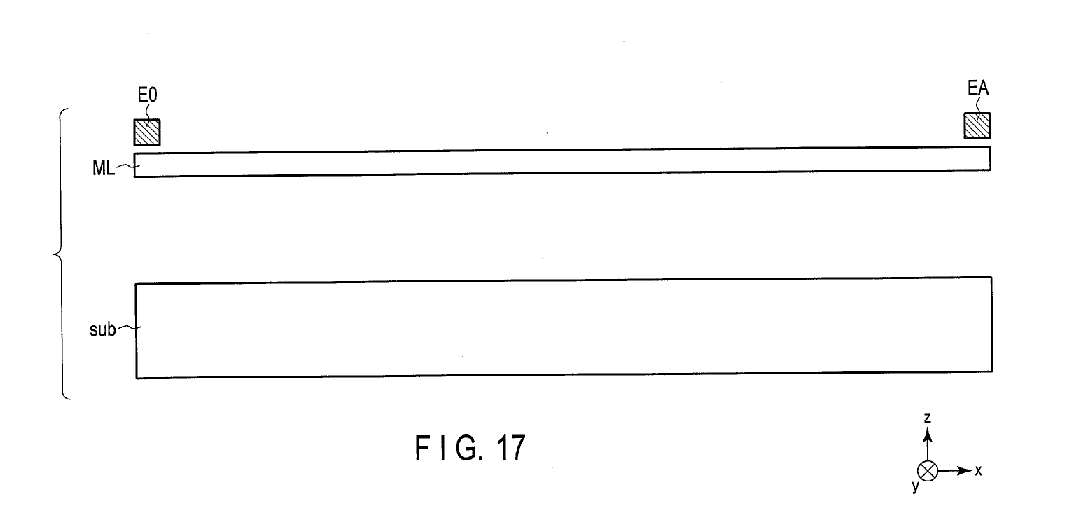

The structure of FIG. 13 can be formed by the following processes. First, the conductive layers C3 and C4 are formed as illustrated in FIG. 15. Specifically, for example, a conductive material which will become the conductive layers C4 is first formed, and this conductive material is processed by patterning with etching into the conductive layers C4 as illustrated in FIG. 15. A conductive material which will become the conductive layers C3 is then formed above, along the z-axis, the conductive layer C3, and this conductive material is processed by patterning with etching into the conductive layers C3.

Holes H are then formed in the conductive layers C3 and C4 where the magnetic wires ML will be formed by etching. The holes H are provided with the insulators IL1 therein, and the holes H are filled with a material for the magnetic wires ML with the insulators therebetween. The via plugs VP1 and VP2 and the conductive layers C11 and C12 are then formed to obtain the structure of FIG. 14.

(Second Modification of First Embodiment)

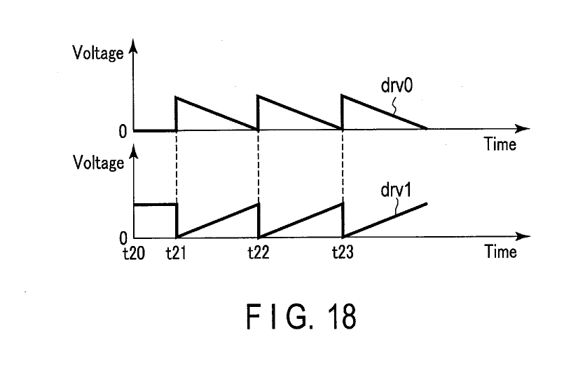

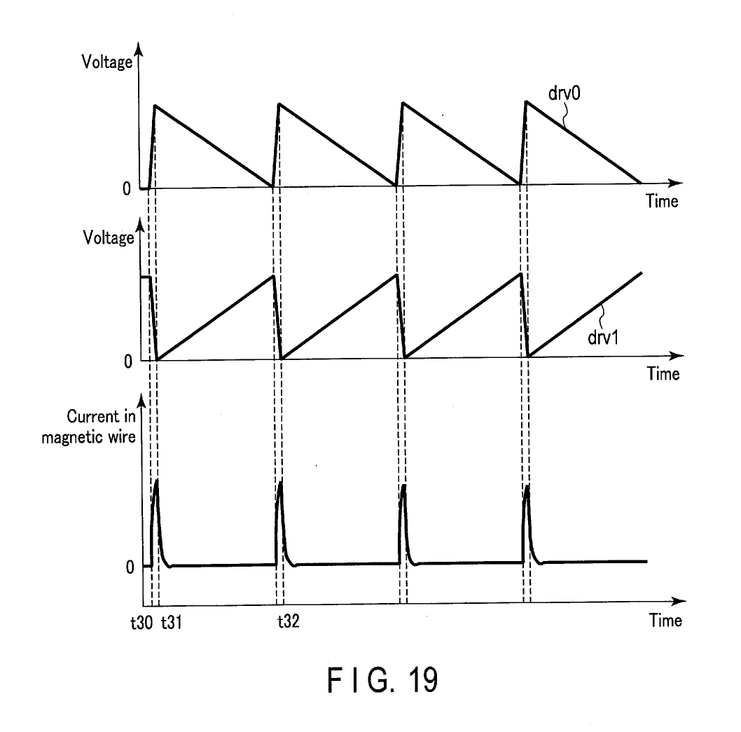

FIG. 16 illustrates a plan view of components involved in magnetic wall shift of a memory device MD of a second modification of the first embodiment. FIG. 17 illustrates the section along line XVII-XVII of FIG. 16.

As illustrated in FIGS. 16 and 17, the magnetic wires ML are located above, along the z-axis, the substrate sub, extend along the x-axis, and line up along the y-axis.

Interconnects E0 and EA for coupling capacities to the magnetic wires ML are provided in the same manner as the interconnects TDL and BDL for the magnetic wire ML which extend along the z-axis as in FIG. 5. Specifically, the interconnect E0 is provided at one end of each of the magnetic wires ML at the same side (for example, the left-hand side in the figures) in the direction in which the magnetic wires ML extend. Moreover, the interconnect EA is provided at the other end of each of the magnetic wires ML at the same side (for example, the right-hand side in the figures) in the direction in which the magnetic wires ML extend. The interconnects E0 and EA are made from a conductive material, face the magnetic wires ML, and are located above, along the z-axis, the magnetic wires ML, for example.

The interconnect E0 faces, for example, the magnetic domain at one end of each of the magnetic wires ML. The interconnect EA faces, for example, the magnetic domain at the other end of each of the magnetic wires ML.

One or both of the interconnects E0 and EA may be located below, along the z-axis, the magnetic wires ML.

One of the interconnects E0 and EA receives one of the output voltage drv0 of the driver DR0 and the output voltage drv1 of the driver DR1. The other of the interconnects E0 and EA receives the other of the output voltage drv0 of the driver DR0 and the output voltage drv1 of the driver DR1.

With the first and second modifications, the advantage of the first embodiment can be obtained.

### Second Embodiment

The second embodiment differs from the first embodiment in waveforms of the output voltages drv0 and drv1 of the driver DR.

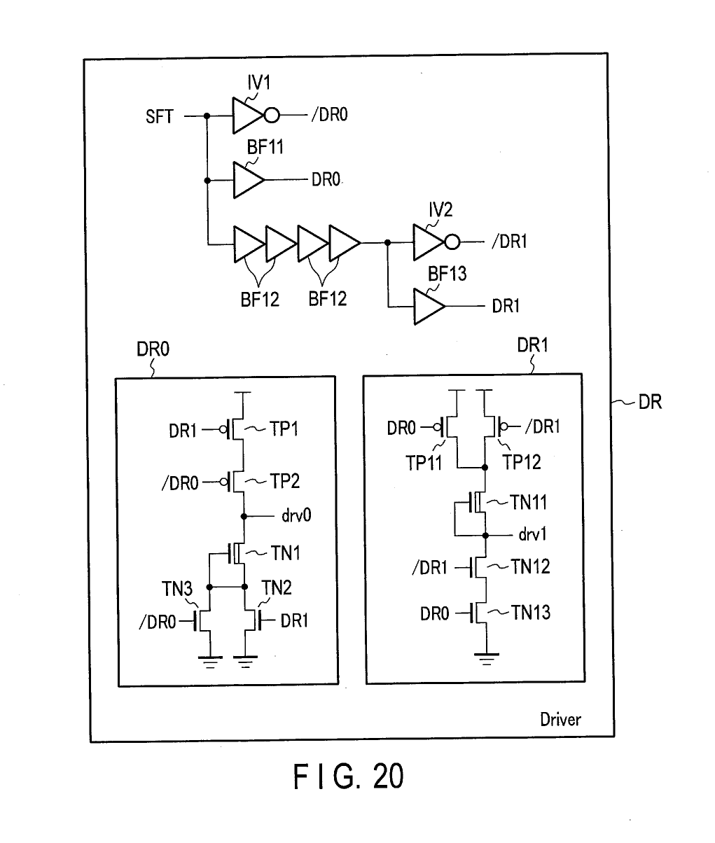

FIG. 18 illustrates the output voltages drv0 and drv1 of the driver DR of a memory device MD of the second embodiment with time. In the second embodiment, each of the output voltage drv0 of the driver DR0 and the output voltage drv1 of the driver DR1 has the shape of a sawtooth waveform. The voltage drv0 rises in a short period, and falls over a time longer than the time for the rise. As a result of the fall, the value of the voltage drv0 returns to the same as, or substantially the same as, or close to the value upon the start of the rise before the fall.

In contrast, the voltage drv1 falls in a short period, and rises over a time longer then the time for the fall. As a result of the rise, the value of the voltage drv1 returns to the same as, or substantially the same as, or close to the value upon the start of the fall before the rise.

As in the first embodiment, the rise of the voltage drv0 and the fall of the voltage drv1 are started at a similar timing, or at substantially the same timing, for example. In FIG. 18, both the rise of the voltage drv0 and the fall of the voltage drv1 are started at time t21, t22, and t23. The quantity of the rise of the voltage drv0 and the quantity of the fall of the voltage drv1 at substantially the same particular times have a similar value, or, substantially the same value, for example.

With the above features, the waveform of the voltage drv0 and the waveform of the voltage drv1 are line-symmetrical with respect to the horizontal axis also in the second embodiment, for example.

During the fall of the voltage drv0 and the rise of the voltage drv1, the inclinations of the fall of the voltage drv0 and the rise of the output voltage drv1 need to be controlled to keep the magnetic walls of the magnetic wire ML from shifting. Unintentional shifts during the fall of the voltage drv0 and the rise of the voltage drv1 can be prevented by the following methods.

A shift of a magnetic wall occurs when an applied current exceeds a particular threshold, and the applied current depends on the magnitude of the potential difference at the positions N0 and N1 in the magnetic wire ML (see, FIG. 7). Furthermore, the changes of the potentials at the positions N0 and N1 depend on the magnitudes of changes of the voltages drv0 and drv1 per unit time, i.e., the magnitudes of inclination. For this reason, when the inclinations of the fall of the voltage drv0 and the rise of the voltage drv1 are too large, a current pulse which may cause magnetic wall shifts can be generated during the fall of the voltage drv0 and the rise of the voltage drv1. Based on this, the voltages drv0 and drv1 need to fall and rise with inclinations that avoid generation of a current pulse which can cause magnetic wall shifts, respectively. The inclinations of the voltages drv0 and drv1 can be adjusted by adjustment of the output section of the drivers DR0 and DR1. The details will be described later.

Moreover, occurrence of unintentional shifts can be prevented also by raising the threshold of the current which causes magnetic wall shifts. As one of the methods for achieving this, the unintentional shifts are suppressed also with the magnetic wires ML having pinning sites as described in the first embodiment to some extent. This is because the presence of the pinning sites makes the move of the magnetic walls from the pinning sites harder to occur. Furthermore, disturbing the arrangement of elements which make the magnetic wires ML can also suppress occurrence of unintentional shifts. To this end, impurities, such as copper and chromium, are introduced into the magnetic wires ML for example. Alternatively, defects may be generated in the arrangement of the elements of the magnetic wires ML.

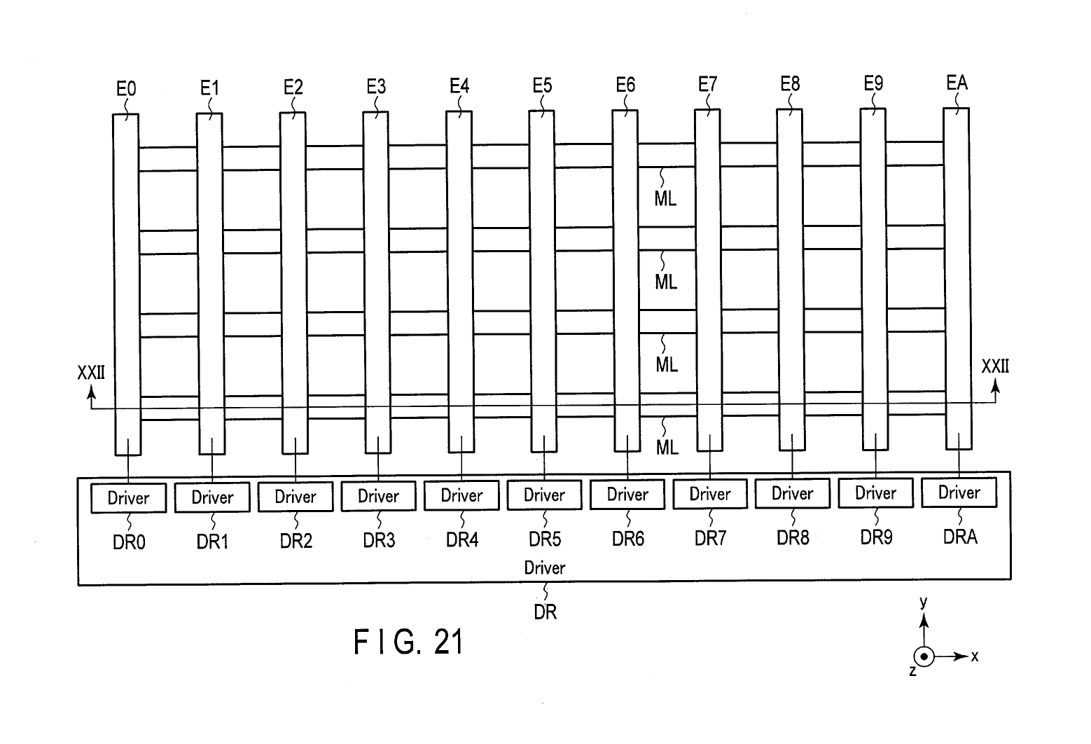

FIG. 19 illustrates a result of a simulation of the waveforms of the voltages drv0 and drv1 with time and the waveform of a current which flows through the magnetic wire over the time. As illustrated in FIG. 19, the waveforms of the voltages drv0 and drv1 are as described with reference to FIG. 18. The rise of the voltage drv0 and the fall of voltage drv1, however, have inclinations due to the RC delay of the drivers DR0 and DR1, the transistors TB and TT, and the interconnects BDL and TDL, and interconnects that connect them.

The rise of the voltage drv0 and the fall of the voltage drv1 make a current flow in a magnetic wire ML during the rise of the voltages drv0 and the fall of the voltage drv1. The waveform of this current rises in a period over which the voltage drv0 rises and the voltage drv1 falls, i.e., in a period over which the voltages drv0 and drv1 change (or, are driven), such as a period from t30 to t31.

After the drive of the voltages drv0 and drv1, the driver DR lowers the voltage drv0 back to the value prior to the rise (for example, the value at t30) until time t32, and raises the voltage drv1 back to the value prior to the fall (for example, the value at t30) until time t32. The length of the period (a relief period) from the end of a drive (for example, time t31) to the start of the next drive (for example, time t32) is a length which should not generate a current pulse which shifts the magnetic walls of the magnetic wires ML of the target of magnetic wall shift as described above. With a relief period with such a length, the waveform of the current returns to zero from the end of the drive (for example, time t31).

In a relief period, a read or write is performed to the magnetic domain in the MTJ structure MS.

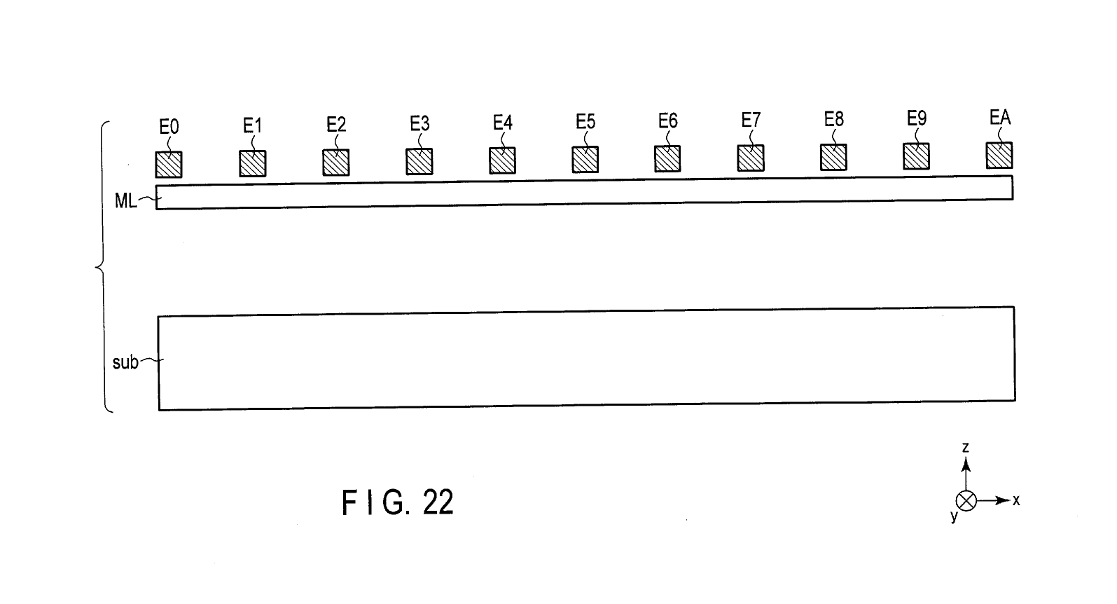

Referring to FIG. 20, the details of the driver DR will now be described. The driver DR has components and connections illustrated in FIG. 20. The driver DR receives the signal SFT from the sequencer SQ. The signal SFT is asserted (or, made high) to shift the magnetic walls, and is maintained to be asserted for a period of shifting the magnetic walls. The signal SFT is received by an inverter IV1. The inverter IV1 outputs a signal /DR0. The sign “/” at the head of the name of the signal represents the inversion logic of the signal without the sign “/”.

The signal SFT is also delayed by a buffer BF11 to be output from a buffer BF11 as a signal DR0. The signal SFT is further received by, among serially-coupled buffers BF12, a buffer BF12 at the first stage. The number of buffers BF12 determines the period of the rise of the output voltage drv0 and the fall of the output voltage drv1, i.e., the width of a current pulse. The lower the number, the shorter the time of the rise of the output voltage drv0 and the fall of the output voltage drv1, and therefore the shorter the width of a pulse.

The output of the buffer BF12 at the last stage of the serially-coupled buffers BF12 serves as a signal /DR1 through an inverter IV2 and serves as a signal DR1 through buffer BF13.

The driver DR0 includes p-type MOS transistors TP1 and TP2 coupled in series. The source of the transistor TP1 is coupled to a node of the power supply potential, and the voltage of the drain of the transistor TP2 is the output voltage drv0. The gate of the transistor TP1 receives the signal DR1. The gate of the transistor TP2 receives the signal /DR0.

The drain of the transistor TP2 is coupled to the drain of an n-type and depletion-type MOS transistor TN1. The source of the transistor TN1 is coupled to the gate of the transistor TN1 and a node of the ground (common) potential via n-type MOS transistors TN2 and TN3 coupled in parallel. The gate of the transistor TN2 receives the signal DR1. The gate of the transistor TN3 receives the signal /DR0.

The driver DR1 includes p-type MOS transistors TP11 and TP12 coupled in parallel. The source of each of the transistors TP11 and TP12 is coupled to the node of the power supply potential. The gate of the transistor TP11 receives the signal DR0, whereas the gate of the transistor TP12 receives the signal /DR1. The drain of each of the transistors TP11 and TP12 is coupled to the drain of an n-type and depletion-type MOS transistor TN11. The voltage of the source of the transistor TN11 is output voltage drv1. The source of the transistor TN11 is coupled to the gate of the transistor TN11, and is further coupled to the node of the ground potential through n-type MOS transistors TN12 and TN13 coupled in series. The gate of the transistor TN12 receives the signal /DR1. The gate of the transistor TN13 receives the signal DR0.

With the components and connections illustrated in FIG. 20, the driver DR can output the voltages drv0 and drv1 of a sawtooth waveform as illustrated in FIG. 19. The higher the drivability of the transistors TP1 and TP2, the quicker the voltage drv0 rises. Generally, the wider the width of the channel and/or the shorter the length of the channel of a transistor, the larger the drivability of the transistor. In contrast, the lower the drivability of the transistors TN1, TN2, and TN3, the slower the output voltage drv0 falls.

Similarly, the higher the drivability of the transistors TP11 and TP12, the quicker the voltage drv1 rises. In contrast, the lower the drivability of the transistor TN11, TN12, and TN13, the slower the voltage drv1 falls.

The first and second modifications of the first embodiment are applicable to the second embodiment.

As described above, according to the second embodiment, the magnetic wires ML have the capacities CC0 and CC1 coupled at both ends, and potential differences are generated in the magnetic wires ML by the rise of the potential through one of the capacities CC0 and CC1 and the fall of the potential through the other as in the first embodiment. This produces the same advantages as in the first embodiment. Moreover, according to the second embodiment, after the rise of the output voltage drv0 and the fall of the output voltage drv1, the output voltage drv0 is slowly lowered back to the original value and the output voltage drv1 is slowly raised back to the original value during a period of a write or read. For this reason, the voltage drv0 does not need to keep rising and the voltage drv1 does not need to keep falling for successive shifts of the magnetic walls. This eliminates the necessity of the driver DR outputting a high voltage, and therefore a circuit for generating and applying a high voltage. The lack of necessity of the circuit for a high voltage prevents the increase of the chip area of the memory device MD and eliminates the necessity of a process exclusive for formation of transistors for a high voltage.

### Third Embodiment

The third embodiment is based on the first and second embodiments.

According to the first and second embodiments, a current is generated in a magnetic wire ML by a potential difference generated with the capacities CC0 and CC1 coupled to the magnetic wire ML. The current generated in a magnetic wire in this way has higher uniformity over the magnetic wire than that of a current directly supplied to the magnetic wire. For this reason, the first and second embodiments enable use of a magnetic wire ML longer than that in an example of a direct supply of a current as described above. This in turn can reduce the total number of the magnetic wires ML in a memory device MD, and the total number of switches coupled to the magnetic wires ML. This is because the number of switches required for a magnetic wire ML is determined and the total number of the magnetic wires ML becomes decreased.

In order to maximize such an advantage of reduction of the number of switches with the first and second embodiments, the magnetic wires ML need to be as long as possible. However, the methods of generation of currents as in the first and second embodiments cannot permit the magnetic wires ML of an infinite length, and a limit exists as to the maximum length of magnetic wires ML.

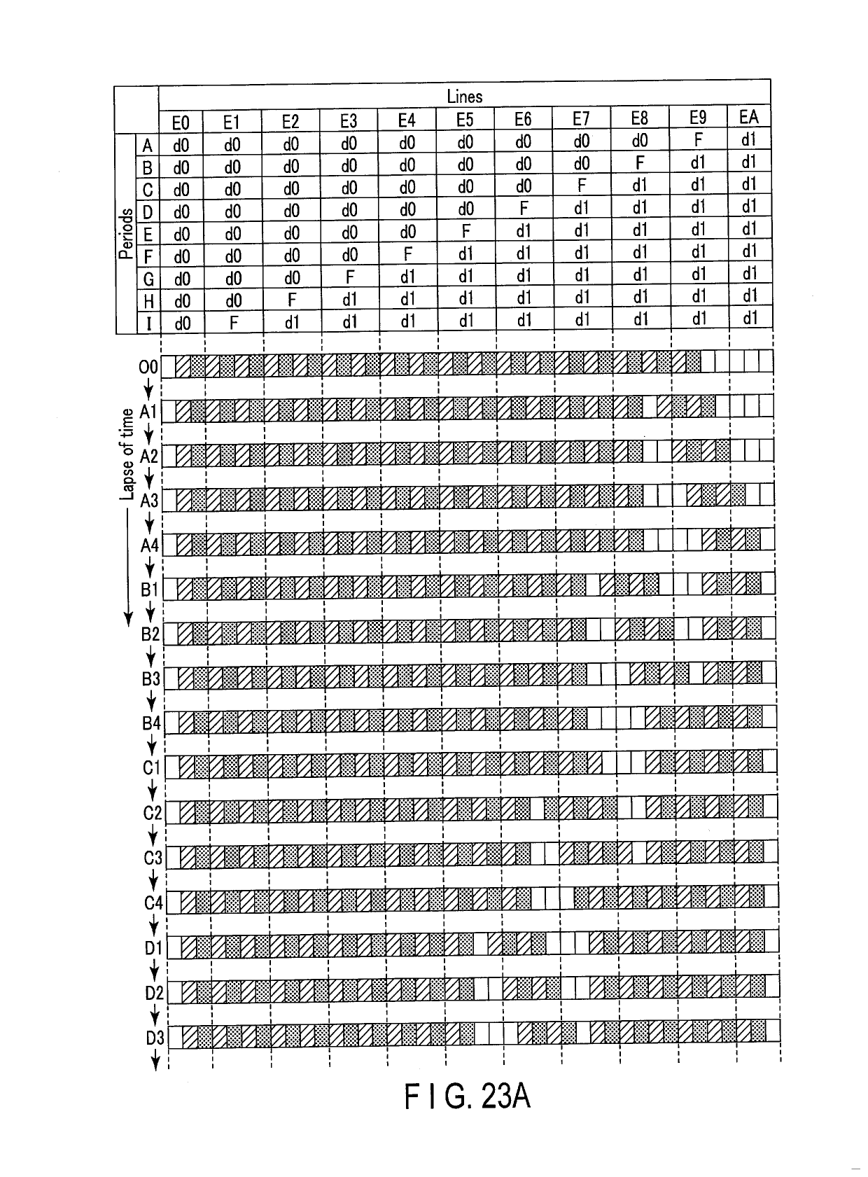

The third embodiment is configured in consideration of such a background. Referring to FIGS. 21, 22, 23A, 23B, 24A, and 24B, the third embodiment will now be described. FIGS. 21, 22, 23A, 23B, 24A, and 24B and the following description are based on an example in which the third embodiment is applied to the structure of the second modification of the first embodiment and the application of the voltages in the second embodiment. The third embodiment is, however, applicable to other embodiments and examples.

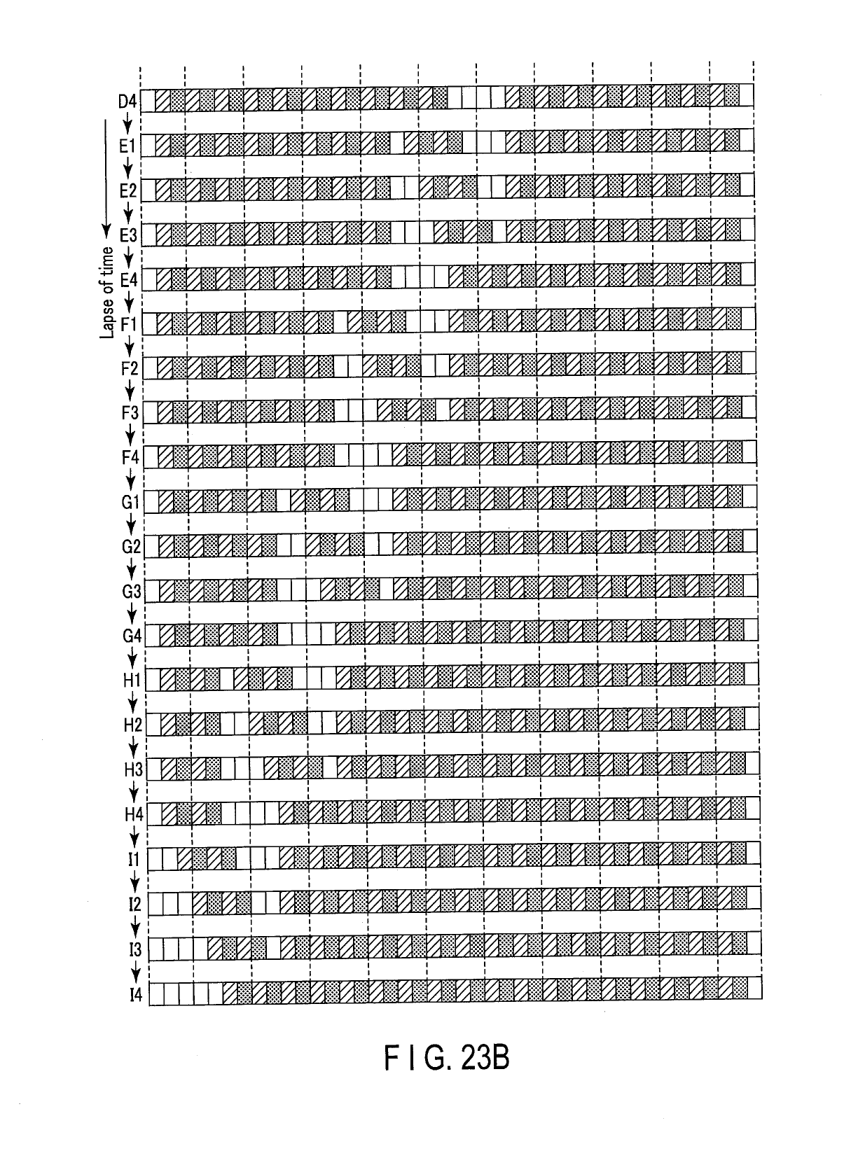

FIG. 21 illustrates a plan view of components involved in magnetic wall shift in a memory device MD of the third embodiment. FIG. 22 illustrates the section along line XXII-XXII of FIG. 21.

In the third embodiment, in addition to the components and arrangement in the second modification of the first embodiment, interconnects E1 to E9 are provided. The interconnects E1 to E9 line up in this order between the interconnects E0 and E9. The number of the interconnects E0 to EA is an example, and more or less interconnects may be provided.

The interconnects E0 to EA are located, for example, above, along the z-axis, the magnetic wires ML, extend along the y-axis, have an interval along the x-axis, and, for example, have an equal interval. One or more of the interconnects E0 to EA may be located below, along the z-axis, the magnetic wires ML.

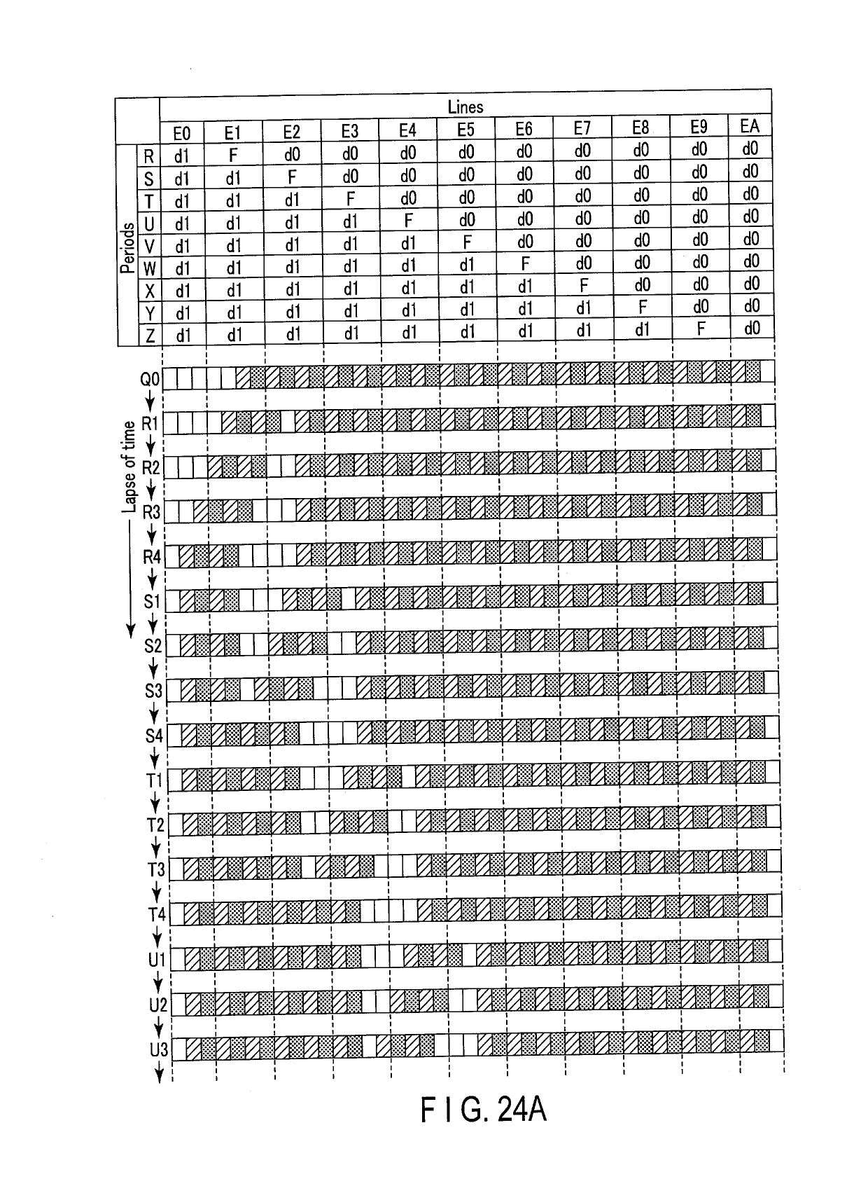

The interconnects E0 to EA are coupled to the drivers DR0 to DRA in the driver DR, respectively. The drivers DR0 to DRA can apply an independent voltage to the interconnects E0 to EA. Applying suitable voltages to the interconnects E0 to EA can shift solely one or more magnetic domains in magnetic wires ML. The details will be described with reference to FIGS. 23A and 23B. For shifting the magnetic walls, the drivers DR0 to DRA apply voltages to the interconnects E0 to EA as described in the following.

FIGS. 23A and 23B illustrate an example of application of voltages for magnetic wall shift according to the third embodiment in order, and illustrate an example of the voltage application to interconnects with time. Each square in FIGS. 23A and 23B represents a magnetic domain. Magnetic domains with one of two types of hatching store valid data, and blank magnetic domains do not store valid data. The upper part of FIG. 23A illustrates voltages applied to the interconnects E (E0 to EA) between each of periods A to I. Four magnetic domains correspond to each of the interconnects E1 to E9. Each of the interconnects E1 to E9 faces the center of the corresponding four magnetic domains, i.e., the boundary of two magnetic domains. In contrast, three magnetic domains correspond to each of the interconnects E0 and EA. The interconnects E0 and EA face, among the three magnetic domains, one at the end of the magnetic wires ML.

The lower sections of FIGS. 23A and 23B illustrate the states of the magnetic domains in periods A to I with transition in each period. In order to shift magnetic walls rightward in FIGS. 23A and 23B, a current is conducted in the magnetic wires ML leftward. To this end, a pulse of a sawtooth waveform, such as the voltage drv0 of the second embodiment (FIG. 19), is applied to right-hand side one of two interconnects E located at both ends of a section whose magnetic walls are to be shifted, and a pulse of a sawtooth waveform, such as the voltage drv1 of the second embodiment, is applied to a left-hand side one of the two. A pulse of a sawtooth waveform, such as the voltage drv0, is a section of the waveform of the voltage drv0 from time t30 to time t32, and will be referred to as “a positive pulse of a sawtooth waveform” in the following. A pulse of a sawtooth waveform, such as the voltage drv1, is a section of the waveform of the voltage drv1 from time t30 to time t32, and will be referred to as “a negative pulse of a sawtooth waveform” in the following. However, note that for formation of a potential difference in magnetic wires ML, a section of the rise or fall of voltages drv0 and drv1 as one pulse, i.e., the section from t30 to t31 of FIG. 19, is only needed.

In FIGS. 23A and 23B, reception of the positive pulse of a sawtooth waveform is represented with sign “d0”, and reception of the negative pulse of a sawtooth waveform with sign “d1”.

A potential difference is generated between two interconnects E which sandwich another interconnect E. For example, during period A, the driver EA applies the positive pulse of a sawtooth waveform to the interconnect EA, the drivers E0 to E8 apply the negative pulses of a sawtooth waveform to the interconnects E0 to E8, respectively, and the interconnect E9 between the interconnects E8 and EA is made to electrically float (or, is not driven at all by the driver E9). The state of the floating is represented with a sign “F” in FIGS. 23A and 23B. As a result of such voltage application, a current pulse as illustrated in the lower part of FIG. 19 flows in the part of the magnetic wires ML between the interconnects E8 and EA from the side of the interconnect EA to the side of the interconnect E8. FIG. 23A illustrates that a set of the positive and negative pulses of a sawtooth waveform was applied four times in the period “A” in the upper section. Specifically, a set of the positive and negative pulses of a sawtooth waveform is applied by the drivers E0 to EA in each period from time “O0” to “A1”, from time “A1” to “A2”, from time “A2” to “A3”, and from time “A3” to “A4”, as illustrated in the lower section of FIG. 23B. With a current of this pulse applied, all the magnetic domains between the interconnects E8 and EA shift rightward over period A (O0 to A4). The magnetic domains on the left of the interconnect E8 do not shift.

As for the remaining periods B to I, the drivers E0 to EA apply the negative pulse of a sawtooth waveform to the left-hand-side one of a pair of interconnects E with another interconnect therebetween and all the interconnects E at the left, the positive pulse of a sawtooth waveform to the right-hand-side one of the pair and all the interconnects E at the right, and the sandwiched interconnect E is made electrically float. In other words, a potential difference is formed only between a pair of interconnects E which define the area of the target of magnetic wall shift, and no potential difference is formed between the remaining interconnects E. As a result, the magnetic domains between the pair of the interconnects E shift rightward.

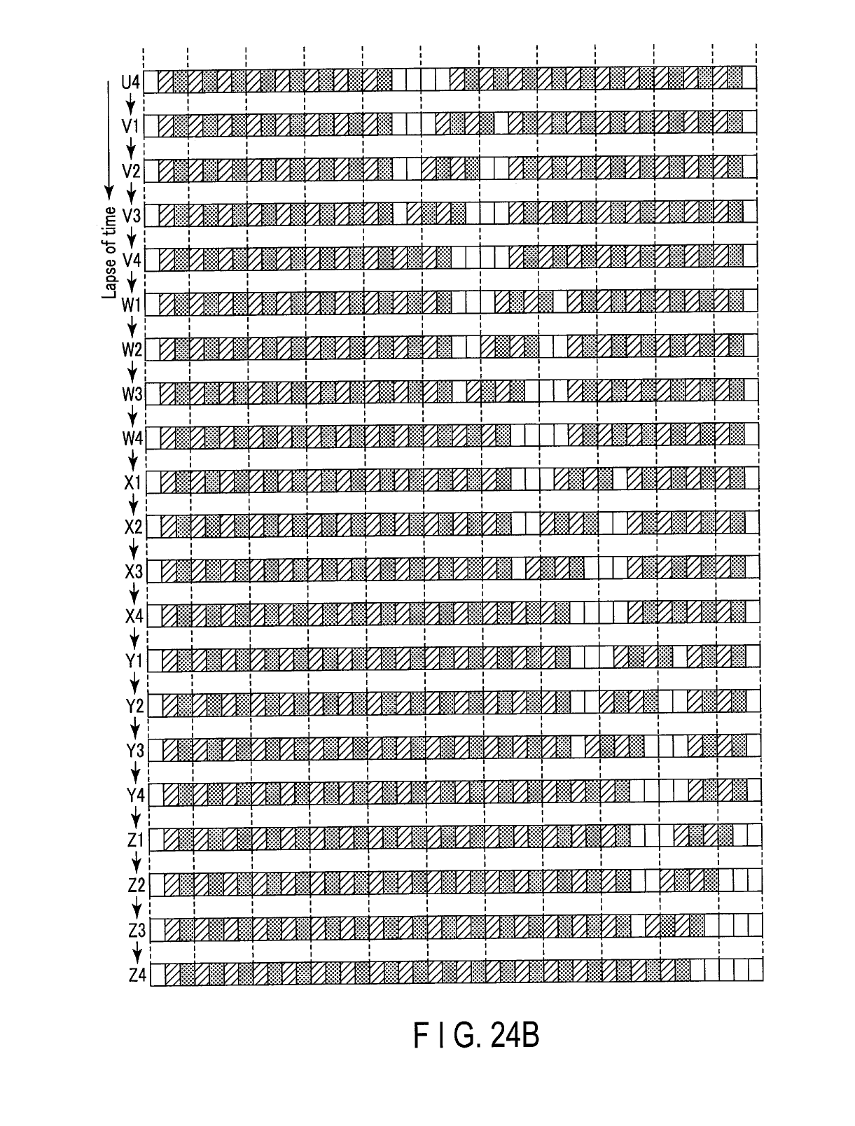

In order to shift the magnetic domains leftward, the drivers E0 to EA apply the voltages of a combination contrary to the combination of the applied voltages of FIGS. 23A and 23B to the interconnects E as illustrated in FIGS. 24A and 24B. The upper section of FIG. 24A illustrates voltages applied to the interconnects E during each of periods R to Z. The lower sections of FIGS. 24A and 24B illustrate the states of the magnetic domains in periods R to Z with transition in each period.

As described above, according to the third embodiment, the magnetic wires ML have the capacities coupled at both ends, and potential differences are generated in the magnetic wires ML by the rise of the potential through one of the capacities and the fall of the potential through the other as in the first embodiment. This produces the same advantages as in the first embodiment. Moreover, according to the third embodiment, additional interconnects E1 to E9 are provided between the interconnects E0 and EA at both ends. Formation of a potential difference in the magnetic wires ML only between positions facing two of the interconnects E0 to EA shifts only the magnetic domains between this pair of interconnects E. Such a partial magnetic wall shift enables shift of the magnetic walls in the magnetic interconnects ML which is still longer than in the first and second embodiments.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A memory device comprising:
a magnetic wire;
a conductive first line which faces one of opposite ends of the magnetic wire at a distance; and
a conductive second line which faces the other of the opposite ends of the magnetic wire at a distance, wherein
a voltage applied to the first line is changed in a positive direction and a second voltage applied to the second line is changed in a negative direction to form a potential difference in the magnetic wire.

2. The device of claim 1, wherein
the first line faces the magnetic wire at a first position of the magnetic wire,
the second line faces the magnetic wire at a second position of the magnetic wire,
change of the voltage applied to the first line has an inclination which changes a potential of the first position of the magnetic wire, and
change of the voltage applied to the second line has an inclination which changes a potential of the second position of the magnetic wire.

3. The device of claim 2, wherein
the change of the voltage applied to the first line and the change of the voltage applied to the second line are performed in parallel.

4. The device of claim 3, wherein
a magnitude of the change of the voltage applied to the first line is substantially the same as a magnitude of the change of the voltage applied to the second line.

5. The device of claim 2, wherein
the magnetic wire has magnetic domains with variable orientation of magnetization,
the magnetic domains line up along a direction in which the magnetic wire extends,
the voltage applied to the first line after changed in a positive direction has a change of a magnitude which does not send in the magnetic wire a current exceeding a current which shifts the magnetic domains, and
the voltage applied to the second line after changed in a negative direction has a change of a magnitude which does not send in the magnetic wire a current exceeding a current which shifts the magnetic domains.

6. The device of claim 5, wherein
the voltage applied to the first line after changed in a positive direction is maintained to be substantially uniform, and
the voltage applied to the second line after changed in a negative direction is maintained to be substantially uniform.

7. The device of claim 5, wherein
the voltage applied to the first line after changed in a positive direction is changed in a negative direction with a magnitude which does not send in the magnetic wire a current exceeding a current which shifts the magnetic domains, and
the voltage applied to the second line after changed in a negative direction is changed in a positive direction with a magnitude which does not send in the magnetic wire a current exceeding a current which shifts the magnetic domains.

8. The device of claim 5, wherein
the device further comprises an insulator which faces the magnetic wire and a pinned layer which sandwiches the insulator with the magnetic layer and which has fixed orientation of magnetization,
a current is sent between the pinned layer and the magnetic wire while the voltage applied to the first line has a change with a magnitude which does not send in the magnetic wire a current exceeding a current which shifts the magnetic domains and while the voltage applied to the second line has a change with a magnitude which does not send in the magnetic wire a current exceeding a current which shifts the magnetic domains.

9. The device of claim 1, wherein
no line which is coupled directly to allow a current to flow through is provided between the first and second lines along the magnetic wire.

10. The device of claim 1, wherein
the magnetic wire has magnetic domains with variable orientation of magnetization, and
the magnetic domains line up along a direction in which the magnetic wire extends.

11. A memory device comprising:
a magnetic wire;
conductive lines which face the magnetic wire at a distance and line up along a direction in which the magnetic wire extends at an interval, wherein
a voltage applied to a first line of the lines is changed in a positive direction and a second voltage applied to a second line of the lines is changed in a negative direction to form a potential difference in the magnetic wire, and
the first and second lines line up with a third line of the lines sandwiched between the first and second lines.

12. The device of claim 11, wherein
the first line faces the magnetic wire at a first position of the magnetic wire,
the second line faces the magnetic wire at a second position of the magnetic wire,
change of the voltage applied to the first line has an inclination which changes a potential of the first position of the magnetic wire, and
change of the voltage applied to the second line has an inclination which changes a potential of the second position of the magnetic wire.

13. The device of claim 12, wherein
the change of the voltage applied to the first line and the change of the voltage applied to the second line are performed in parallel.

14. The device of claim 13, wherein
a magnitude of the change of the voltage applied to the first line is substantially the same as a magnitude of the change of the voltage applied to the second line.

15. The device of claim 12, wherein
the magnetic wire has magnetic domains with variable orientation of magnetization,
the magnetic domains line up along a direction in which the magnetic wire extends,
the voltage applied to the first line after changed in a positive direction has a change of a magnitude which does not send in the magnetic wire a current exceeding a current which shifts the magnetic domains, and
the voltage applied to the second line after changed in a negative direction has a change of a magnitude which does not send in the magnetic wire a current exceeding a current which shifts the magnetic domains.

16. The device of claim 15, wherein
the voltage applied to the first line after changed in a positive direction is maintained to be substantially uniform, and
the voltage applied to the second line after changed in a negative direction is maintained to be substantially uniform.

17. The device of claim 15, wherein
the voltage applied to the first line after changed in a positive direction is changed in a negative direction with a magnitude which does not send in the magnetic wire a current exceeding a current which shifts the magnetic domains, and
the voltage applied to the second line after changed in a negative direction is changed in a positive direction with a magnitude which does not send in the magnetic wire a current exceeding a current which shifts the magnetic domains.

18. The device of claim 15, wherein
the device further comprises an insulator which faces the magnetic wire and a pinned layer which sandwiches the insulator with the magnetic layer and which has fixed orientation of magnetization,
a current is sent between the pinned layer and the magnetic wire while the voltage applied to the first line has a change with a magnitude which does not send in the magnetic wire a current exceeding a current which shifts the magnetic domains and while the voltage applied to the second line has a change with a magnitude which does not send in the magnetic wire a current exceeding a current which shifts the magnetic domains.

19. The device of claim 11, wherein
the magnetic wire has magnetic domains with variable orientation of magnetization, and
the magnetic domains line up along a direction in which the magnetic wire extends.
